(19) United States
(12) Patent Application Publication
(10) Pub. No.: US 2026/0101548 A1
(43) Pub. Date: Apr. 9, 2026

(54) SEMICONDUCTOR DEVICE

(71) Applicant: ROHM CO., LTD., Kyoto-shi (JP)

(72) Inventors: Seigo MORI, Kyoto-shi (JP); Yuki NAKANO, Kyoto-shi (JP)

(73) Assignee: ROHM CO., LTD., Kyoto-shi (JP)

(21) Appl. No.: 19/415,844

(22) Filed: Dec. 11, 2025

Related U.S. Application Data
(63) Continuation of application No. PCT/JP2024/017093, filed on May 8, 2024.

(30) Foreign Application Priority Data
Jun. 26, 2023 (JP) 2023-104405

(51) Int. Cl. H10D 62/10; H10D 12/00; H10D 30/66; H10D 62/832

(52) U.S. Cl. CPC H10D 62/109; H10D 12/415; H10D 12/481; H10D 30/665; H10D 30/668; H10D 62/107; H10D 62/127; H10D 62/8325

(57) ABSTRACT

A semiconductor device includes a chip that has a first principal surface and a second principal surface on an opposite side thereto, a first impurity region of a first conductivity type that is formed in a surface layer portion of the first principal surface, a second impurity region of a second conductivity type that is formed in a surface layer portion of the first impurity region, a third impurity region of the first conductivity type that is formed in a surface layer portion of the second impurity region, a plurality of trenches that reach the first impurity region through the third impurity region and the second impurity region from the first principal surface, and an electric field relaxation structure of the second conductivity type that is formed integrally with the second impurity region and straddles bottom walls of the plurality of trenches.

### CROSS-REFERENCE TO RELATED APPLICATIONS

The present application is a bypass continuation application of International Patent Application No. PCT/JP2024/017093, filed on May 8, 2024, which corresponds to Japanese Patent Application No. 2023-104405, filed on Jun. 26, 2023 with the Japan Patent Office, and the entire disclosure of the applications are incorporated herein by reference.

### TECHNICAL FIELD

The present disclosure relates to a semiconductor device.

### BACKGROUND ART

Patent Literature 1 (US 2015/0028351 A1 Specification) discloses an electronic device having an impurity region introduced into a silicon carbide layer by a channeling implantation method.

### BRIEF DESCRIPTION OF DRAWINGS

FIG. 1 is a plan view showing a semiconductor device according to a preferred embodiment of the present disclosure.

FIG. 2 is a sectional view taken along line II-II shown in FIG. 1.

FIG. 3 is a plan view showing a layout example of a chip.

FIG. 4 is a perspective view showing the layout example of the chip.

FIG. 5 is a plan view showing an active region and a trench structure.

FIG. 6 is a sectional perspective view showing the active region and the trench structure.

FIG. 7 is an enlarged sectional view showing the trench structure.

FIG. 8 is an enlarged sectional view showing the trench structure.

FIG. 9 is an enlarged sectional view showing the trench structure.

FIG. 10 is a perspective view showing an arrangement of an outer peripheral region.

FIG. 11 is a sectional view showing a principal portion of the outer peripheral region.

FIG. 12 is a schematic view showing a wafer used in manufacture of the semiconductor device.

FIG. 13 is a flowchart showing a manufacturing method example of the semiconductor device.

FIG. 14A to FIG. 14H are views showing the manufacturing method example of the semiconductor device.

FIG. 15 is a view showing a first modification example of the semiconductor device.

FIG. 16 is a view showing a second modification example of the semiconductor device.

FIG. 17 is a view showing a third modification example of the semiconductor device.

FIG. 18 is a view showing a fourth modification example of the semiconductor device.

FIG. 19 is a view showing a fifth modification example of the semiconductor device.

FIG. 20 is a view showing a sixth modification example of the semiconductor device.

### DESCRIPTION OF EMBODIMENTS

Next, a preferred embodiment of the present disclosure shall be described in detail with reference to the attached drawings.

The attached drawings are all schematic views and are not strictly illustrated, and scales, proportions, angles and the like thereof do not always match. Identical reference signs are given to corresponding structures among the attached drawings, and duplicate descriptions thereof shall be omitted or simplified. For the structures whose description have been omitted or simplified, the description given before the omission or simplification shall apply.

When the wording “substantially equal” is used in this description, the wording includes a numerical value (shape) equal to a numerical value (shape) of a comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type,” the “p-type” may be referred to as a “first conductivity type,” and the “n-type” may be referred to as a “second conductivity type.” As a matter of course, the “n-type” may be referred to as the “first conductivity type,” and the “p-type” may be referred to as the “second conductivity type” instead. The “p-type” is a conductivity type due to a trivalent element and the “n-type” is a conductivity type due to a pentavalent element. Unless noted in particular otherwise, the trivalent element is at least one type among boron, aluminum, gallium, and indium. Unless noted in particular otherwise, the pentavalent element is at least one type among nitrogen, phosphorus, arsenic, antimony, and bismuth.

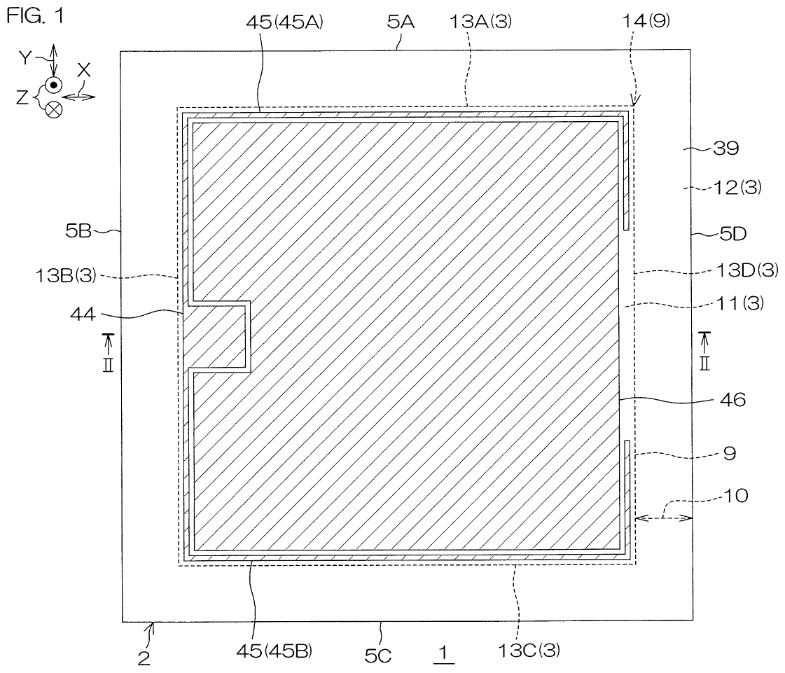

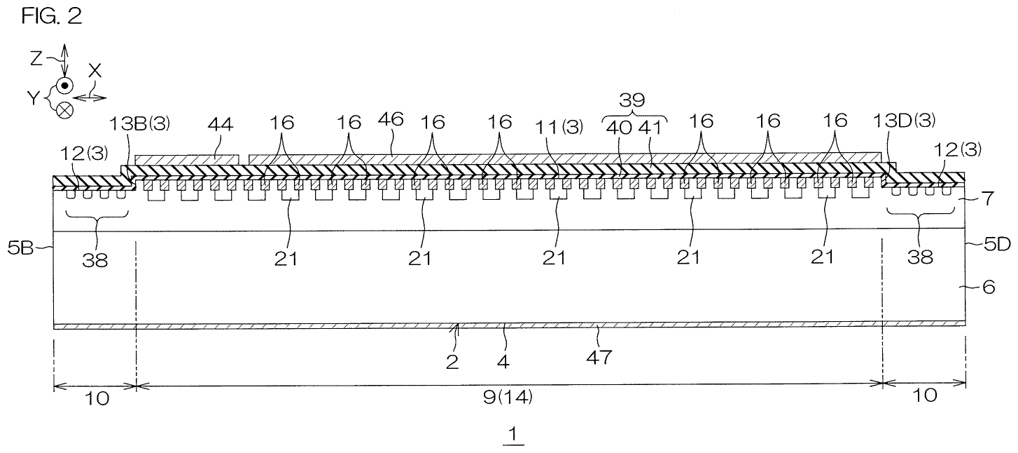

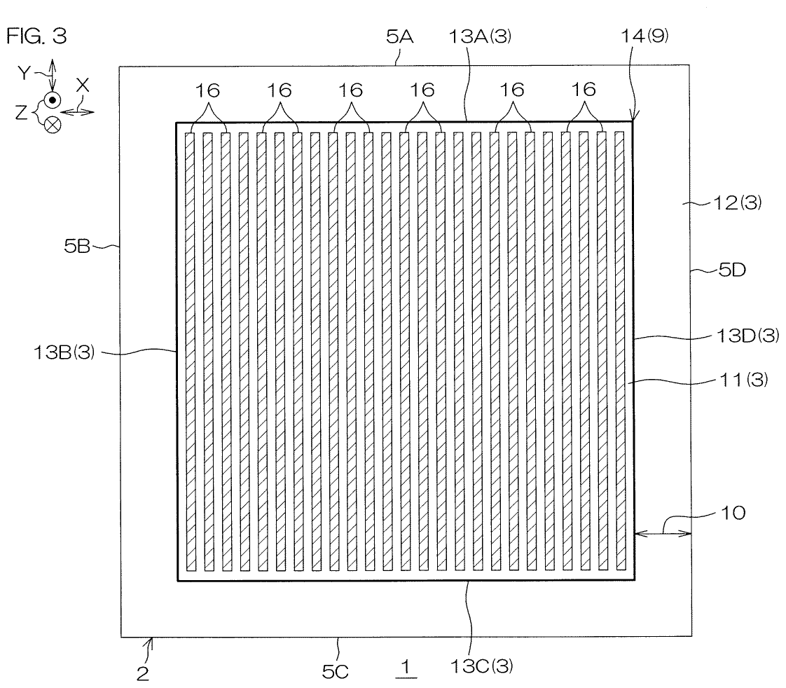

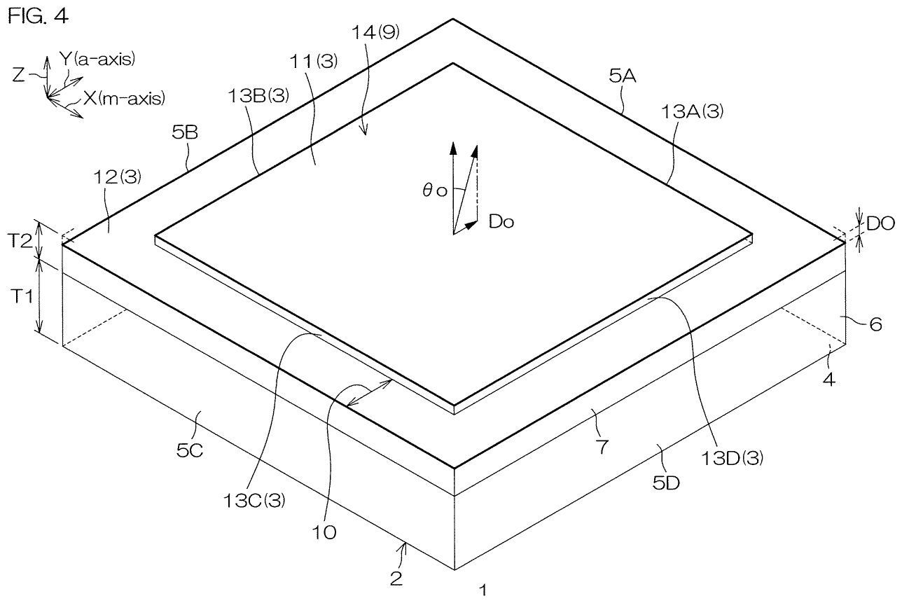

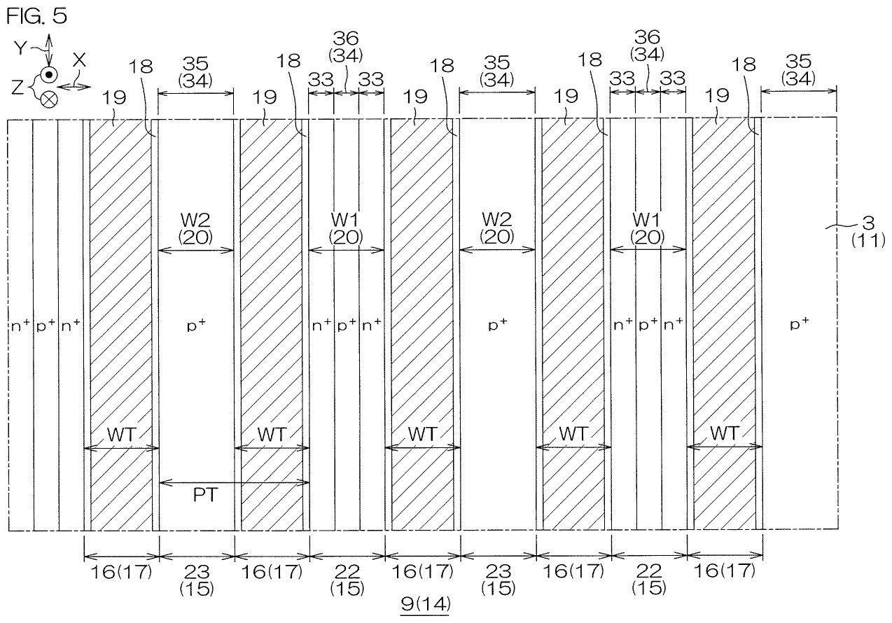

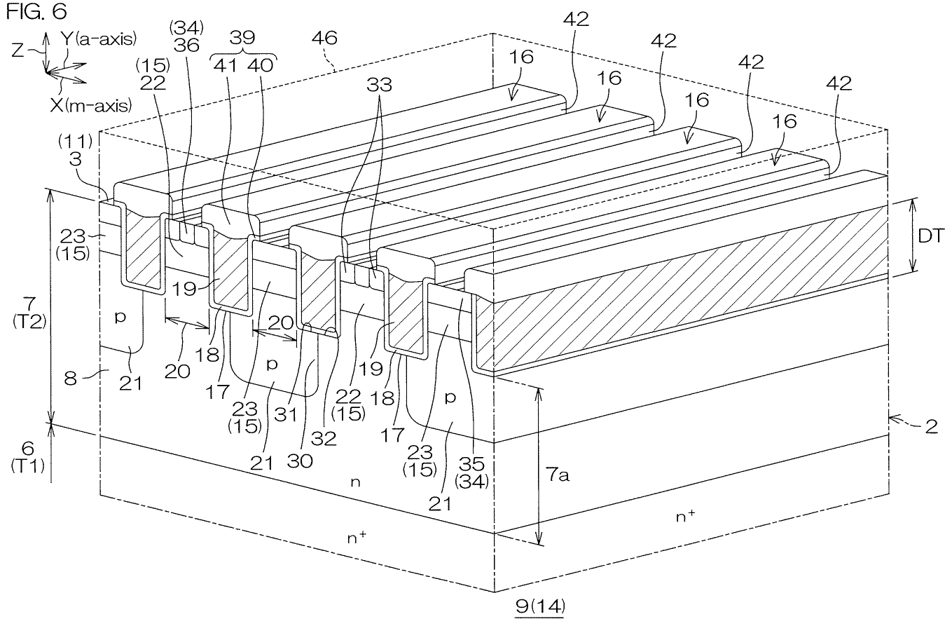

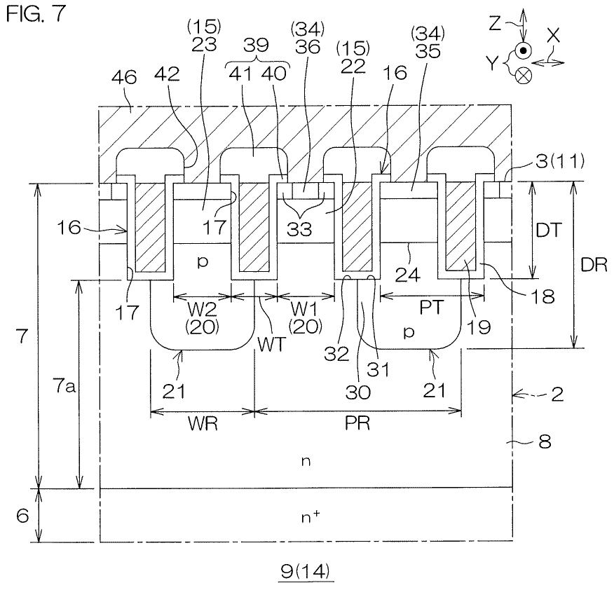

FIG. 1 is a plan view showing a semiconductor device 1 according to the preferred embodiment. FIG. 2 is a sectional view taken along line II-II shown in FIG. 1. FIG. 3 is a plan view showing a layout example of a chip 2. FIG. 4 is a perspective view showing the layout example of the chip 2. FIG. 5 is a plan view showing trench structures 16 together with an active region 9. FIG. 6 is a sectional perspective view showing the trench structures 16 and an electric field relaxation structure 21 together with the active region 9. FIG. 7 to FIG. 9 are enlarged sectional views showing the trench structures 16 and the electric field relaxation structure 21. FIG. 7 to FIG. 9 are identical sectional views differing only in the assigned reference signs. A shape of the electric field relaxation structure 21 shall be described from various aspects with reference to FIG. 7 to FIG. 9.

With reference to FIG. 1 to FIG. 9, the semiconductor device 1 includes the chip 2 that includes an SiC monocrystal. The chip 2 may be referred to as an “SiC chip” or a “semiconductor chip.” In this embodiment, the chip 2 is constituted of the SiC monocrystal, which is a hexagonal crystal, and is formed in a rectangular parallelepiped shape. The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 is constituted of the 4H-SiC monocrystal is to be given, but the chip 2 may be constituted of another polytype instead.

The chip 2 has a first principal surface 3 on one side, a second principal surface 4 on the other side, and first to fourth side surfaces 5A to 5D connecting the first principal surface 3 and the second principal surface 4. In a plan view as viewed from a vertical direction Z (hereinafter referred to simply as “plan view”), the first principal surface 3 and the second principal surface 4 are formed in quadrilateral shapes. The vertical direction Z is also a thickness direction of the chip 2 and a normal direction to the first principal surface 3 (the second principal surface 4). The first principal surface 3 and the second principal surface 4 may be formed in a square shape or a rectangular shape in plan view.

The first principal surface 3 and the second principal surface 4 are preferably formed by c-planes of the SiC monocrystal. In this case, preferably, the first principal surface 3 is formed by a silicon plane (a (0001) plane) of the SiC monocrystal and the second principal surface 4 is formed by a carbon plane (a (000-1) plane) of the SiC monocrystal.

In regard to a circumferential direction of the chip 2 with the first side surface 5A as a starting point (counterclockwise in FIG. 1), the second side surface 5B is connected to the first side surface 5A, the third side surface 5C is connected to the second side surface 5B, and the fourth side surface 5D is connected to the first side surface 5A and the third side surface 5C. The first side surface 5A and the third side surface 5C extend in a first direction X oriented along the first principal surface 3 and are opposed in a second direction Y intersecting (specifically, orthogonal to) the first direction X. The second side surface 5B and the fourth side surface 5D extend in the second direction Y and are opposed in the first direction X.

In this embodiment, the first direction X is an m-axis direction (a [1-100] direction) of the SiC monocrystal and the second direction Y is an a-axis direction (a [11-20] direction) of the SiC monocrystal. As a matter of course, the first direction X may instead be the a-axis direction of the SiC monocrystal and the second direction Y may instead be the m-axis direction of the SiC monocrystal.

An XY plane that includes the first direction X and the second direction Y forms a horizontal plane that is orthogonal to the vertical direction Z. In the following, an axis extending along the vertical direction Z is expressed at times as a “vertical axis.” Also, in the following, the first direction X and the second direction Y is expressed at times as “horizontal directions.” Horizontal directions are also directions that extend along the first principal surface 3.

With reference to FIG. 4, the chip 2 (the first principal surface 3 and the second principal surface 4) has an off angle θo inclined at a predetermined angle in a predetermined off direction Do with respect to the c-plane of the SiC monocrystal. That is, a c-axis (a (0001) axis) of the SiC monocrystal is inclined by just the off angle θo toward the off direction Do from the vertical axis. Also, the c-plane of the SiC monocrystal is inclined by just the off angle θo with respect to the horizontal plane.

The off direction Do is preferably the a-axis direction (that is, the second direction Y) of the SiC monocrystal. The off angle θo may exceed 0° and be not more than 10°. The off angle θo may have a value belonging to any one range among exceeding 0° and not more than 1°, not less than 1° and not more than 2.5°, not less than 2.5° and not more than 5°, not less than 5° and not more than 7.5°, and not less than 7.5° and not more than 10°.

The off angle θo is preferably not more than 5°. The off angle θo is particularly preferably not less than 2° and not more than 4.5°. The off angle θo is typically set in a range of 4°±0.1°. As a matter of course, this Description does not exclude an embodiment in which the off angle θo is 0° (that is, an embodiment in which the first principal surface 3 is a just surface with respect to the c-plane).

The chip 2 includes a base layer 6 of an n-type that is constituted of an SiC monocrystal. The base layer 6 may be referred to as a “drain region,” a “base SiC layer,” a “base region,” etc. The base layer 6 extends in a layered shape in the horizontal directions and forms the second principal surface 4 and portions of the first to fourth side surfaces 5A to 5D. In this embodiment, the base layer 6 is constituted of a substrate made of the SiC monocrystal (in other words, an SiC substrate). The base layer 6 has the off direction Do and the off angle θo described above.

The base layer 6 may have an n-type impurity concentration of not less than 1×10¹⁸ cm⁻³ and not more than 1×10²¹ cm⁻³ as a peak value. The base layer 6 preferably has an n-type impurity concentration that is substantially fixed in a thickness direction. The n-type impurity concentration of the base layer 6 is preferably adjusted by a single type of pentavalent element. The n-type impurity concentration of the base layer 6 is particularly preferably adjusted by a pentavalent element other than phosphorus. In this embodiment, the n-type impurity concentration of the base layer 6 is adjusted by nitrogen.

The base layer 6 has a first thickness T1. The first thickness T1 may be not less than 5 μm and not more than 300 μm. The first thickness T1 may have a value belonging to any one range among not less than 5 μm and not more than 50 μm, not less than 50 μm and not more than 100 μm, not less than 100 μm and not more than 150 μm, not less than 150 μm and not more than 200 μm, not less than 200 μm and not more than 250 μm, and not less than 250 μm and not more than 300 μm. The first thickness T1 is preferably not less than 50 μm and not more than 250 μm.

The chip 2 includes a semiconductor layer 7 made of the SiC monocrystal that is laminated on the base layer 6. The semiconductor layer 7 as an example of a first impurity region may be referred to as a “drift region,” an “SiC layer,” a “semiconductor region,” etc. The semiconductor layer 7 extends in a layered shape in the horizontal directions and forms the first principal surface 3 and portions of the first to fourth side surfaces 5A to 5D. The semiconductor layer 7 is constituted of an epitaxial layer (that is, an SiC epitaxial layer) formed by crystal growth with the base layer 6 as a starting point.

The semiconductor layer 7 has a lower end and an upper end. The lower end of the semiconductor layer 7 is a crystal growth starting point and the upper end of the semiconductor layer 7 is a crystal growth end point. The lower end of the semiconductor layer 7 is also a bottom portion of the semiconductor layer 7. The semiconductor layer 7 is formed by continuous crystal growth from the base layer 6 and therefore, the lower end of the semiconductor layer 7 coincides with an upper end of the base layer 6.

The semiconductor layer 7 includes a drift region 8 of the n-type. In this embodiment, the drift region 8 is formed by a portion of the semiconductor layer 7 (a portion of the n-type). In more detail, the drift region 8 is formed by the portion of the semiconductor layer 7 on the second principal surface 4 side with respect to a body region 15 (to be described below) and the electric field relaxation structure 21 (to be described below) in the vertical direction Z.

A boundary portion between the base layer 6 and the semiconductor layer 7 is not necessarily visually recognizable and can be evaluated and/or determined indirectly from other arrangements and elements. The semiconductor layer 7 has an off direction Do and the off angle θo that substantially coincide with the off direction Do and the off angle θo of the base layer 6.

An n-type impurity concentration of the semiconductor layer 7 (the drift region 8) is preferably less than the n-type impurity concentration of the base layer 6. The semiconductor layer 7 may have an n-type impurity concentration of not less than 1×10¹⁵ cm⁻³ and not more than 1×10¹⁸ cm⁻³ as a peak value. The n-type impurity concentration of the semiconductor layer 7 may be substantially fixed in a thickness direction. As a matter of course, the n-type impurity concentration of the semiconductor layer 7 may have a concentration gradient that increases gradually and/or decreases gradually in a lamination direction (a crystal growth direction).

In this embodiment, the n-type impurity concentration of the semiconductor layer 7 is adjusted by nitrogen. The semiconductor layer 7 may have an n-type impurity concentration that is adjusted by at least one type of pentavalent element. For example, the n-type impurity concentration of the semiconductor layer 7 may be adjusted by at least one type among nitrogen, phosphorus, arsenic, antimony, and bismuth. The semiconductor layer 7 preferably contains a pentavalent element other than phosphorus.

The semiconductor layer 7 has a second thickness T2 less than the first thickness T1. The second thickness T2 may be not less than 1 μm and not more than 10 μm. The second thickness T2 may have a value belonging to any one range among not less than 1 μm and not more than 2 μm, not less than 2 μm and not more than 4 μm, not less than 4 μm and not more than 6 μm, not less than 6 μm and not more than 8 μm, and not less than 8 μm and not more than 10 μm. The second thickness T2 is preferably not less than 2 μm and not more than 8 μm.

The semiconductor device 1 includes the active region 9 set in the chip 2. The active region 9 is set in an inner portion of the chip 2 at intervals from peripheral edges (the first to fourth side surfaces 5A to 5D) of the chip 2 in plan view. The active region 9 is set in a polygonal shape (in this embodiment, a quadrilateral shape) having four sides parallel to the peripheral edges of the chip 2 in plan view. A planar area of the active region 9 is preferably not less than 50% and not more than 90% of a planar area of the first principal surface 3.

The semiconductor device 1 includes an outer peripheral region 10 that, in the chip 2, is set outside the active region 9. The outer peripheral region 10 is provided in a region between the peripheral edges of the chip 2 and the active region 9 in plan view. The outer peripheral region 10 extends in a band shape along the active region 9 and is set to a polygonal annular shape (in this embodiment, a quadrilateral annular shape) that surrounds the active region 9 in plan view.

The semiconductor device 1 includes an active surface 11, an outer surface 12, and first to fourth connecting surfaces 13A to 13D that are formed in the first principal surface 3. The active surface 11, the outer surface 12, and the first to fourth connecting surfaces 13A to 13D demarcate an active mesa 14 in the first principal surface 3.

The active surface 11 may be referred to as a “first surface portion,” the outer surface 12 may be referred to as a “second surface portion,” the first to fourth connecting surfaces 13A to 13D may be referred to as “connecting surface portions,” and the active mesa 14 may be referred to as an “active mesa portion.” The active surface 11, the outer surface 12, and the first to fourth connecting surfaces 13A to 13D (that is, the active mesa 14) may be considered as components of the chip 2 (the first principal surface 3).

The active surface 11 is formed in the active region 9. That is, the active surface 11 is formed at intervals inward from the peripheral edges of the first principal surface 3 (from the first to fourth side surfaces 5A to 5D). The active surface 11 has a flat surface extending in the first direction X and the second direction Y. In this embodiment, the active surface 11 is formed by the c-plane (an Si plane). In this embodiment, the active surface 11 is formed in a quadrilateral shape having four sides parallel to the first to fourth side surfaces 5A to 5D in plan view.

The outer surface 12 is formed in the outer peripheral region 10. That is, the outer surface 12 is formed outside the active surface 11. The outer surface 12 is recessed in the thickness direction of the chip 2 (toward the second principal surface 4 side) with respect to the active surface 11. Specifically, in this embodiment, the outer surface 12 is recessed to a depth less than the thickness of the semiconductor layer 7 such as to expose the semiconductor layer 7. That is, the outer surface 12 faces the base layer 6 with a portion of the semiconductor layer 7 interposed therebetween and exposes the semiconductor layer 7.

The outer surface 12 extends in a band shape along the active surface 11 in plan view and is formed in an annular shape (specifically, a quadrilateral annular shape) surrounding the active surface 11. The outer surface 12 has a flat surface extending in the first direction X and the second direction Y and is formed substantially parallel to the active surface 11. In this embodiment, the outer surface 12 is formed by the c-plane (the Si plane). The outer surface 12 is continuous to the first to fourth side surfaces 5A to 5D.

The outer surface 12 has an outer peripheral depth DO. The outer peripheral depth DO may be not less than 0.1 μm and not more than 2 μm. The outer peripheral depth DO may have a value belonging to any one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, and not less than 1.5 μm and not more than 2 μm. The outer peripheral depth DO is preferably not less than 0.1 μm and not more than 1.5 μm.

The first to fourth connecting surfaces 13A to 13D extend in the vertical direction Z and connect the active surface 11 and the outer surface 12. The first connecting surface 13A is positioned at the first side surface 5A side, the second connecting surface 13B is positioned at the second side surface 5B side, the third connecting surface 13C is positioned at the third side surface 5C side, and the fourth connecting surface 13D is positioned at the fourth side surface 5D side. The first connecting surface 13A and the third connecting surface 13C extend in the first direction X and are opposed in the second direction Y. The second connecting surface 13B and the fourth connecting surface 13D extend in the second direction Y and are opposed in the first direction X.

The first to fourth connecting surfaces 13A to 13D may extend substantially vertically between the active surface 11 and the outer surface 12 such as to demarcate the active mesa 14 of a quadrilateral columnar shape. The first to fourth connecting surfaces 13A to 13D may be inclined obliquely downward from the active surface 11 toward the outer surface 12 such as to demarcate the active mesa 14 of a quadrilateral pyramid shape instead. The active mesa 14 is thus demarcated in a projecting shape on the semiconductor layer 7 in the first principal surface 3. The active mesa 14 is formed just on the semiconductor layer 7 and is not formed on the base layer 6.

With reference to FIG. 6 to FIG. 9, the semiconductor device 1 includes the body region 15 of the p-type formed in a surface layer portion of the first principal surface 3 (the active surface 11). In this embodiment, the body region 15 as an example of a second impurity region is formed in a layered shape extending along the active surface 11. The body region 15 may be formed in an entirety of the active surface 11 and may be exposed from the first to fourth connecting surfaces 13A to 13D. The body region 15 is formed at an interval to the active surface 11 side from the lower end of the semiconductor layer 7. The body region 15 is preferably formed at an interval to the active surface 11 side from a depth position of the outer surface 12 and is exposed from the active surface 11.

The body region 15 may have a p-type impurity concentration of not less than 1×10¹⁵ cm⁻³ and not more than 1×10¹⁸ cm⁻³ as a peak value. The p-type impurity concentration of the body region 15 is preferably adjusted by at least one type of trivalent element. The trivalent element of the body region 15 may be at least one type among boron, aluminum, gallium, and indium.

The semiconductor device 1 includes the plurality of trench structures 16 of a trench electrode type that are formed in the first principal surface 3 (the active surface 11) in the active region 9. The trench structures 16 may be referred to as “gate structures,” “trench gate structures,” etc. A gate potential is applied as a control potential to the plurality of trench structures 16. The plurality of trench structures 16 control inversion and non-inversion of channels (current paths) inside the body region 15 in response to the gate potential.

The plurality of trench structures 16 are arranged at intervals inward from peripheral edges of the active surface 11 (from the first to fourth connecting surfaces 13A to 13D) in the active region 9. In this embodiment, the plurality of trench structures 16 are arranged at intervals in the first direction X and are each formed in a band shape extending in the second direction Y.

That is, the plurality of trench structures 16 are arranged at intervals in the m-axis direction and each extend in the a-axis direction. Also, in this embodiment, the plurality of trench structures 16 are arranged as stripes extending in the a-axis direction (the second direction Y). An extension direction of the plurality of trench structures 16 coincides with the off direction Do of the semiconductor layer 7.

The plurality of trench structures 16 are formed at intervals to the first principal surface 3 (the active surface 11) side from the lower end of the semiconductor layer 7 (from the base layer 6) and faces the base layer 6 with a portion of the semiconductor layer 7 interposed therebetween. The plurality of trench structures 16 demarcate a lower region 7a in a region between bottom walls of the plurality of trench structures 16 and the lower end of the semiconductor layer 7 (the base layer 6).

Each trench structure 16 has a trench width WT in an alignment direction and has a trench depth DT in the vertical direction Z. The trench width WT is preferably less than the second thickness T2 of the semiconductor layer 7. The trench width WT may be not less than 0.1 μm and not more than 5 μm.

The trench width WT may have a value belonging to any one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The trench depth DT is preferably less than the second thickness T2 of the semiconductor layer 7. The trench depth DT is particularly preferably substantially equal to the outer peripheral depth DO described above. As a matter of course, the trench depth DT may be not less than the outer peripheral depth DO or may be less than the outer peripheral depth DO.

The trench depth DT is preferably greater than the trench width WT. That is, each of the plurality of trench structures 16 preferably has an aspect ratio DT/WT of extending in a vertically long columnar shape. The aspect ratio DT/WT is a ratio of the trench width WT with respect to the trench depth DT. The trench depth DT may be not less than 0.1 μm and not more than 5 μm.

The trench depth DT may have a value belonging to any one range among not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 3 μm, not less than 3 μm and not more than 4 μm, and not less than 4 μm and not more than 5 μm. The trench depth DT is preferably not less than 0.1 μm and not more than 1.5 μm, and more preferably not less than 0.5 μm and not more than 1.5 μm.

The plurality of trench structures 16 are arranged at intervals, each of a trench pitch PT, in the first direction X. The trench pitch PT is preferably less than the second thickness T2 of the semiconductor layer 7. The trench pitch PT is preferably less than the trench depth DT. The trench pitch PT may be not less than 0.1 μm and not more than 5 μm.

The trench pitch PT may have a value belonging to any one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The trench pitch PT is preferably not less than 0.5 μm and not more than 3 μm, and more preferably not less than 0.5 μm and not more than 1.5 μm.

Each trench structure 16 includes a trench 17, an insulating film 18, and an embedded electrode 19. The trench 17 is formed in the active surface 11 and demarcates wall surfaces (side walls and a bottom wall) of the trench structure 16. A bottom wall of the trench 17 preferably has a portion that extends flatly. A mesa portion 20 formed by a portion of the semiconductor layer 7 is formed between the trenches 17 that are mutually adjacent. The mesa portion 20 may be referred to as an “element mesa portion.” In this embodiment, a plurality of the trenches 17 and a plurality of the mesa portions 20 are each formed in a band shape extending along the second direction Y and are alternately arranged in the first direction X. The plurality of trenches 17 and the plurality of mesa portions 20 are arranged as stripes as a whole.

A flat portion of the bottom wall of the trench 17 particularly preferably extends substantially parallel to the first principal surface 3. That is, the bottom wall of the trench 17 preferably has the off angle θo inclined at a predetermined angle in a predetermined off direction Do with respect to the c-plane. That is, the bottom wall of the trench 17 preferably has a flat portion that extends in the off direction Do. As a matter of course, the bottom wall of the trench 17 may instead be curved in an arcuate shape toward the lower end side of the semiconductor layer 7.

The insulating film 18 covers wall surfaces of the trench 17. The insulating film 18 may include at least one among a silicon oxide film, a silicon nitride film, and a silicon oxynitride film. In this embodiment, the insulating film 18 has a single layer structure constituted of the silicon oxide film. The insulating film 18 particularly preferably includes the silicon oxide film constituted of an oxide of the chip 2.

The embedded electrode 19 is embedded in the trench 17 and faces the channel with the insulating film 18 interposed therebetween. In this embodiment, the embedded electrode 19 faces the body region 15 with the insulating film 18 interposed therebetween. The embedded electrode 19 may contain a conductive polysilicon of the p-type or the n-type.

The semiconductor device 1 includes a plurality of the electric field relaxation structures 21 of the p-type formed at intervals in the horizontal direction inside the semiconductor layer 7. Specifically, the plurality of electric field relaxation structures 21 are formed in the mesa portions 20 and the lower region 7a inside the semiconductor layer 7. The plurality of electric field relaxation structures 21 are formed in a thickness range between the lower end of the semiconductor layer 7 and the bottom walls of the plurality of trench structures 16.

Inside the lower region 7a, the plurality of electric field relaxation structures 21 are arranged at intervals in the first direction X and are each formed in a band shape extending in the second direction Y. That is, the plurality of electric field relaxation structures 21 are arranged at intervals in the m-axis direction and extend in the a-axis direction of the SiC monocrystal. The plurality of electric field relaxation structures 21 are formed as stripes extending in the a-axis direction (the second direction Y) and an extension direction of the plurality of electric field relaxation structures 21 coincides with the off direction Do of the semiconductor layer 7.

The plurality of electric field relaxation structures 21 are arranged at intervals, each of a relaxation pitch PR, in the first direction X. The relaxation pitch PR is preferably not less than twice the trench pitch PT.

The relaxation pitch PR may have a value belonging to any one range among not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The relaxation pitch PR is preferably not less than 2.5 μm and not more than 3 μm. In this case, the trench pitch PT is preferably not less than 0.5 μm and not more than 1.5 μm.

Each electric field relaxation structure 21 is formed integrally with the body region 15 and straddles the bottom walls of the plurality of trenches 17. In this embodiment, each electric field relaxation structure 21 extends downward further than the bottom wall of the trench 17 in the vertical direction Z from the body region 15 sandwiched between the two trenches 17 that are mutually adjacent, widens along the horizontal directions along the first principal surface 3, and overlaps the bottom walls of the trenches 17 on both sides.

Each electric field relaxation structure 21 covers the bottom wall of the trench 17. In other words, each electric field relaxation structure 21 forms at least a part of the side walls and at least a part of the bottom wall of the trench 17 and is in contact with the insulating film 18. Each electric field relaxation structure 21 has, inside each trench 17, a substantially L-shaped exposed surface exposed as a lower portion of the side wall of the corresponding trench 17 and the bottom wall of the corresponding trench 17 continuous with the lower portion of the side wall.

The body region 15 includes a channel portion 22 and a non-channel portion 23. The channel portion 22 is physically and electrically separated from the electric field relaxation structure 21. A channel is formed along the wall surface of the trench 17 adjacent to the channel portion 22. The non-channel portion 23 is physically and electrically integral with the electric field relaxation structure 21. The non-channel portion 23 has a bottom wall covered with the electric field relaxation structure 21 from below.

The channel portion 22 and the non-channel portion 23 may be alternately arranged in the first direction X as shown in FIG. 7 to FIG. 9, or a plurality of the channel portions 22 may be interposed between the non-channel portions 23 that are mutually adjacent. That is, the plurality of electric field relaxation structures 21 may be alternately connected to the plurality of mesa portions 20 arranged with the trench 17 interposed therebetween in the first direction X, or the plurality of mesa portions 20 to which the electric field relaxation structures 21 are not connected may be interposed between the mesa portions 20 to which the electric field relaxation structures 21 are connected.

In this embodiment, the channel portion 22 and the non-channel portion 23 have an equal width in the first direction X. A first width W1 of the mesa portion 20 that forms the channel portion 22 may be equal to a second width W2 of the mesa portion 20 that forms the non-channel portion 23. That the first width W1=the second width W2 is obtained by aligning the plurality of trenches 17 at equal intervals (the trench pitch PT) in the first direction X.

A boundary portion 24 is formed between the electric field relaxation structure 21 and the bottom portion of the non-channel portion 23 between the trenches 17 that are mutually adjacent. The boundary portion 24 is formed in a rectilinear shape in sectional view which divides the mesa portion 20 along the horizontal direction from the side wall of the trench 17 on one side to the side wall of the trench 17 on the other side. The boundary portion 24 divides the mesa portion 20 into the body region 15 (the non-channel portion 23) on the first principal surface 3 side and the electric field relaxation structure 21 on the second principal surface 4 side.

Since both the body region 15 (the non-channel portion 23) and the electric field relaxation structure 21 are of the p-type, the boundary portion 24 may not be able to be clearly defined by image analysis (for example, SEM image analysis). That the body region 15 and the electric field relaxation structure 21 continue in the vertical direction Z may be confirmed, for example, by acquiring a profile of a p-type impurity concentration in the vertical direction Z from the first principal surface 3 toward the second principal surface 4.

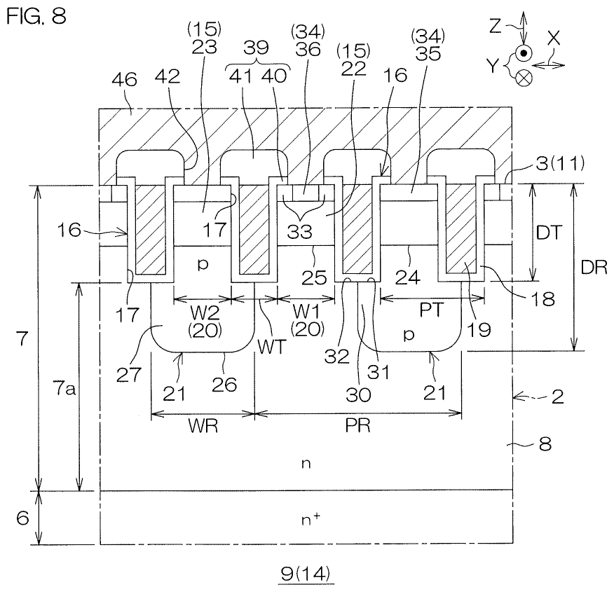

With reference to FIG. 8, by reflecting that both the body region 15 and the electric field relaxation structure 21 are of the p-type, the body region 15 corresponding to the channel portion 22 may be referred to as a “first body region 25 of the second conductivity type,” and an integral object of the body region 15 corresponding to the non-channel portion 23 and the electric field relaxation structure 21 may be referred to as a “second body region 26 of the second conductivity type.” In this case, the first body region 25 and the second body region 26 may be alternately arranged in the first direction X as shown in FIG. 8, or a plurality of the first body regions 25 may be interposed between the second body regions 26 that are mutually adjacent.

The first body region 25 is formed only in the mesa portion 20 between the trenches 17 that are mutually adjacent and has a bottom portion further to the first principal surface 3 side than the bottom wall of the trench 17. On the other hand, the second body region 26 has a mesa portion 20 between the trenches 17 that are mutually adjacent and a protrusion portion 27 protruding from the mesa portion 20 further to the second principal surface 4 side than the bottom wall of the trench 17. The protrusion portion 27 of the second body region 26 widens along the horizontal directions along the first principal surface 3, overlaps the bottom walls of the trenches 17 on both sides, and covers the bottom walls of the trenches 17 from below.

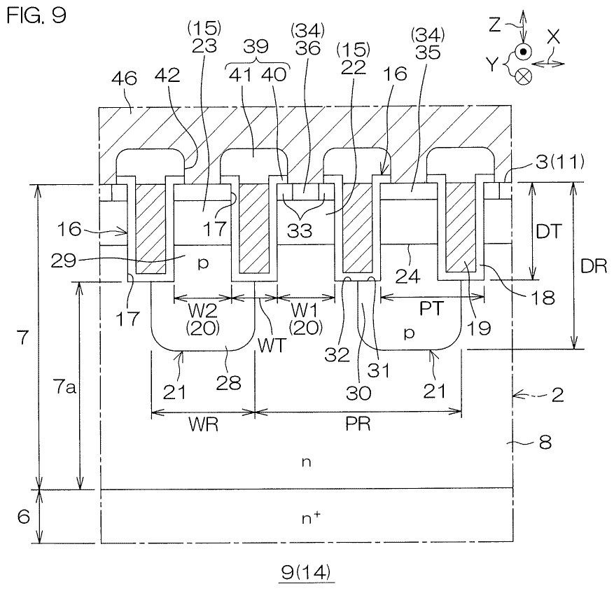

With reference to FIG. 9, in another aspect, each electric field relaxation structure 21 may integrally include a base portion 28 further to the second principal surface 4 side than the bottom walls of the two trenches 17 that are mutually adjacent, and a protrusion portion 29 sandwiched between the two trenches 17 that are mutually adjacent.

The base portion 28 overlaps the two trenches 17 that are mutually adjacent and crosses a region between the two trenches 17 in the first direction X. The base portion 28 has a width wider than the trench pitch PT. The base portion 28 has an end portion projecting further to the outer side in the horizontal directions than a region directly below the mesa portion 20.

The protrusion portion 29 extends from the base portion 28 to an inside of the mesa portion 20 along the side wall of each trench 17 and is connected to a bottom portion of the body region 15. The protrusion portion 29 is formed over an entirety of the mesa portion 20 from the bottom wall of the trench 17 to the body region 15 in the vertical direction Z.

With reference to FIG. 7 to FIG. 9, each electric field relaxation structures 21 (the second body region 26) may have an end portion 30 at a central position of the bottom wall of the trench 17 further to the non-channel portion 23 side than the wall surface (the side wall) of the trench 17 on the channel portion 22 side in a width direction of the trench 17. The bottom wall of the trench 17 may thereby have a first portion 31 that is formed on the non-channel portion 23 side in the width direction of the trench 17 and covered with the electric field relaxation structure 21. Also, the bottom wall of the trench 17 may have a second portion 32 that is formed on the channel portion 22 side with respect to the first portion 31 and covered with the semiconductor layer 7 (the drift region 8). A current path can be sufficiently secured along the wall surfaces (the side wall and the bottom wall) of the trench 17 on the channel portion 22 side since a portion of the bottom wall of the trench 17 on the channel portion 22 side is covered with the drift region 8. On-resistance can thereby be reduced.

A bottom portion of each electric field relaxation structure 21 may have a planar shape parallel or substantially parallel to the first principal surface 3 in the first direction X and the second direction Y. Therefore, in this embodiment, a portion of each electric field relaxation structure 21 further to the second principal surface 4 side than the bottom walls of the trench 17 (the protrusion portion 27 of the second body region 26) is formed in a substantially quadrilateral shape in sectional view.

A p-type impurity concentration of the electric field relaxation structure 21 is preferably higher than the p-type impurity concentration of the body region 15. The electric field relaxation structure 21 may have a p-type impurity concentration of not less than 1×10¹⁶ cm⁻³ and not more than 1×10¹⁹ cm⁻³ as a peak value. The p-type impurity concentration of the electric field relaxation structure 21 may be substantially fixed in a thickness direction. As a matter of course, the p-type impurity concentration of the electric field relaxation structure 21 may have a concentration gradient that increases gradually and/or decreases gradually in the lamination direction (crystal growth direction).

The electric field relaxation structure 21 has a relaxation depth DR greater than the depth of the trench 17 in the vertical direction Z. More preferably, the relaxation depth DR of the electric field relaxation structure 21 is not less than twice the trench depth DT. As a matter of course, the relaxation depth DR may be less than twice the trench depth DT.

The relaxation depth DR may have a value belonging to any one range among exceeding 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 3 μm, not less than 3 μm and not more than 4 μm, and not less than 4 μm and not more than 5 μm. The relaxation depth DR is preferably not less than 2 μm and not more than 3 μm, and in this case, the trench depth DT is preferably not less than 0.5 μm and not more than 1.5 μm.

The plurality of electric field relaxation structures 21 each have a relaxation width WR in the alignment direction. The relaxation width WR is preferably wider than at least the second width W2 (the width of the mesa portion 20 of the non-channel portion 23). As a matter of course, the relaxation width WR may be the same width as the second width W2.

The relaxation width WR may be not less than 0.25 μm and not more than 5 μm. The relaxation width WR may have a value belonging to any one range among not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The semiconductor device 1 includes a plurality of source regions 33 that is formed at one side of the plurality of trench structures 16 in the surface layer portion of the first principal surface 3 (the active surface 11). The plurality of source regions 33 as an example of third impurity regions are formed in a surface layer portion of the body region 15. In this embodiment, the plurality of source regions 33 are selectively formed in the channel portion 22, of the plurality of body regions 15 including the channel portion 22 and the non-channel portion 23.

The plurality of source regions 33 have a higher n-type impurity concentration (a peak value) than that of the semiconductor layer 7. The plurality of source regions 33 may have an n-type impurity concentration of not less than 1×10¹⁸ cm⁻³ and not more than 1×10²¹ cm⁻³ as a peak value.

With reference to FIG. 5, the plurality of source regions 33 extend in band shapes in the extension direction of the corresponding trench structures 16 in plan view. The plurality of source regions 33 are formed at intervals from the bottom portion of the body region 15 toward the active surface 11 and faces the drift region 8 directly below with a portion of the body region 15 in the vertical direction Z interposed therebetween. The plurality of source regions 33, together with the plurality of drift regions 8 directly below, demarcate channels (current paths) that extend along the wall surfaces of the corresponding trench structures 16.

The semiconductor device 1 includes a plurality of contact regions 34 that are formed in regions between the plurality of trench structures 16 in the surface layer portion of the first principal surface 3 (the active surface 11). The plurality of contact regions 34 are formed in the surface layer portion of the body region 15.

The plurality of contact regions 34 have a higher p-type impurity concentration (a peak value) than the p-type impurity concentration (the peak value) of the body region 15. The p-type impurity concentration (the peak value) of the plurality of contact regions 34 is higher than the p-type impurity concentration (the peak value) of the plurality of electric field relaxation structures 21. The plurality of contact regions 34 may have a p-type impurity concentration of not less than 1×10¹⁸ cm⁻³ and not more than 1×10²¹ cm⁻³ as a peak value.

The plurality of contact regions 34 includes a first contact region 35 and a second contact region 36. The first contact region 35 is formed in the non-channel portion 23, and the second contact region 36 is formed in the channel portion 22.

The first contact region 35 is formed over the entire first principal surface 3 between one of the trench structures 16 on one side and the other one of the trench structures 16 on the other side of the non-channel portion 23. The first contact region 35 extends in a band shape in the extension direction of the plurality of trench structures 16. The first contact region 35 crosses the mesa portion 20 of the non-channel portion 23 from the trench structure 16 on the one side to the trench structure 16 on the other side of the non-channel portion 23.

The first contact region 35 is exposed to the wall surfaces (the side walls) of the trenches 17 on both sides in the first direction X of the non-channel portion 23 and is in contact with the insulating film 18. The first contact regions 35 are formed at intervals from the bottom portion of the body region 15 toward the active surface 11 and faces the drift region 8 directly below, with the body region 15 and a portion of the electric field relaxation structure 21 interposed therebetween in the vertical direction Z.

The second contact regions 36 are interposed in regions between the plurality of source regions 33 adjacent to each other in the channel portion 22 and extend in a band shape in the extension direction of the plurality of trench structures 16. The second contact regions 36 are formed at intervals to the active surface 11 side from the bottom portion of the body region 15 and faces the drift region 8 directly below, with a portion of the body region 15 in the vertical direction Z interposed therebetween.

The source regions 33 are thus selectively formed in the channel portion 22, of the channel portion 22 and the non-channel portion 23. On the other hand, in this embodiment, the source region 33 is not formed in the non-channel portion 23, and the first contact region 35 is formed in the entire surface layer portion of the body region 15. A function of the channel portion 22 to form the current path and a function of the non-channel portion 23 to secure electrical contact with the body region 15 can thereby be divided. As a result, ON-operation can be efficiently performed.

In the non-channel portion 23, since a lower portion of the body region 15 is completely covered with the electric field relaxation structure 21, the non-channel portion is not highly effective as a channel. Therefore, in the non-channel portion 23, potential of the body region 15 can be stabilized by forming the first contact region 35 in the entire surface layer portion of the body region 15.

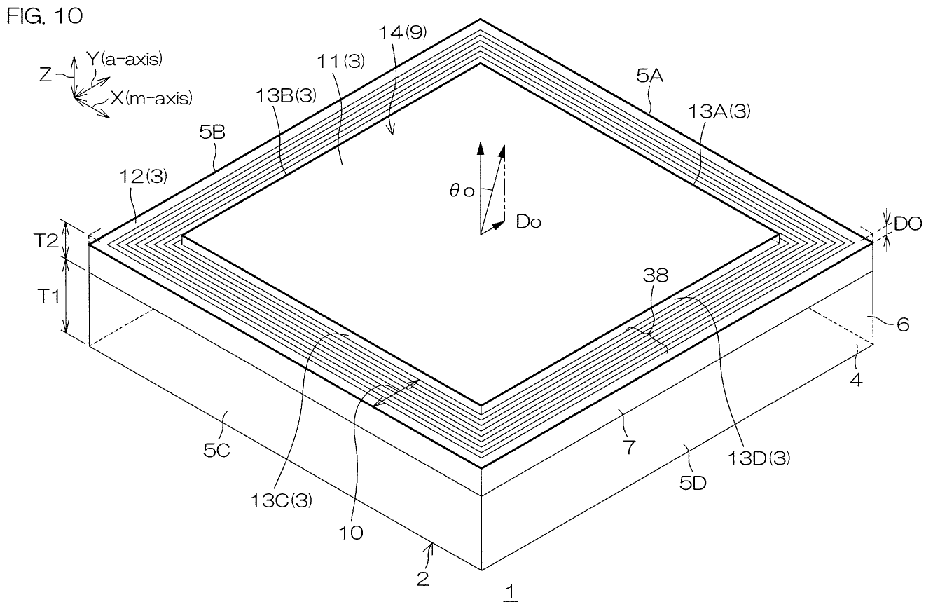

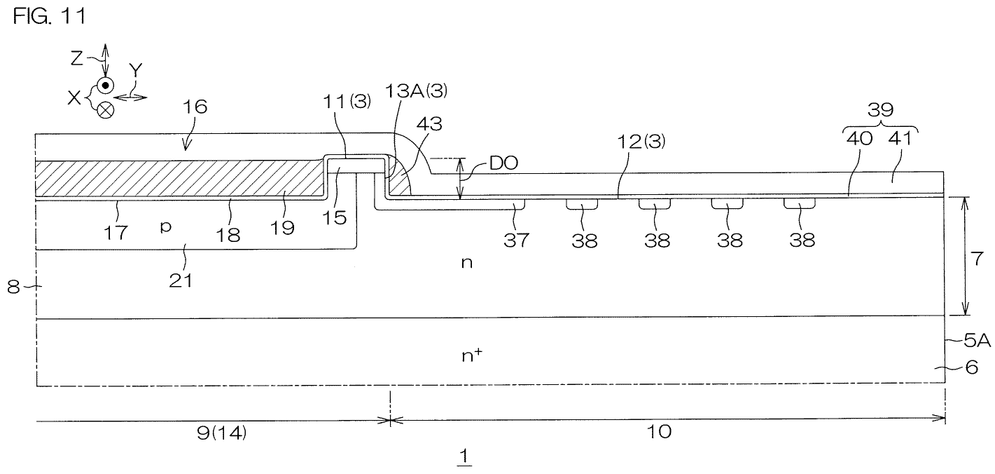

Hereinafter, an arrangement on the outer peripheral region 10 side shall be described. FIG. 10 is a perspective view showing an arrangement of the outer peripheral region 10. FIG. 11 is a sectional view showing a principal portion of the outer peripheral region 10.

The semiconductor device 1 includes a well region 37 of the p-type formed in a surface layer portion of the outer surface 12. In plan view, the well region 37 is formed at intervals to the active surface 11 side from the peripheral edges of the outer surface 12 (from the first to fourth side surfaces 5A to 5D) and extends in a band shape along the active surface 11. In this embodiment, the well region 37 is formed in an annular shape (specifically, a quadrilateral annular shape) surrounding the active surface 11 in plan view.

The well region 37 is led out from the surface layer portion of the outer surface 12 to the first to fourth connecting surfaces 13A to 13D sides and extends along surface layer portions of the first to fourth connecting surfaces 13A to 13D. The well region 37 is electrically connected to the body region 15 in the surface layer portion of the active surface 11.

The well region 37 is formed at an interval to the outer surface 12 side from the lower end of the semiconductor layer 7 and faces the base layer 6 with a portion of the semiconductor layer 7 interposed therebetween. The well region 37 forms a pn junction portion with the semiconductor region 7. The well region 37 may have a p-type impurity concentration of not less than 1×10¹⁵ cm⁻³ and not more than 1×10¹⁸ cm⁻³ as a peak value. The well region 37 has a p-type impurity concentration lower than the p-type impurity concentration of the contact region 34.

The p-type impurity concentration of the well region 37 may be higher than the p-type impurity concentration of the body region 15. As a matter of course, the p-type impurity concentration of the well region 37 may be lower than that of the body regions 15. The p-type impurity concentration of the well region 37 is preferably adjusted by at least one type of trivalent element. The trivalent element of the well region 37 may be the same type as a trivalent element of the electric field relaxation structure 21, or may be a type different from the trivalent element of the electric field relaxation structure 21. The trivalent element of the well region 37 may be at least one type among boron, aluminum, gallium, and indium.

The semiconductor device 1 includes at least one (preferably not less than two and not more than twenty) of field regions 38 of the p-type formed in the surface layer portion of the outer surface 12 (the first principal surface 3) in the outer peripheral region 10. The number of the plurality of the field regions 38 is typically not less than 4 and not more than 8. The plurality of field regions 38 are formed in an electrically floating state and relax an electric field inside the chip 2 at peripheral edge portions of the first principal surface 3. The number, width, depth, p-type impurity concentration, etc., of the field regions 38 are arbitrary and can take on any of various values in accordance with the electric field to be relaxed.

In this embodiment, the plurality of field regions 38 are arranged at intervals from the peripheral edges of the active surface 11 (from the first to fourth connecting surfaces 13A to 13D) and from the peripheral edges (the first to fourth side surfaces 5A to 5D) of the chip 2. Specifically, the plurality of field regions 38 are arranged at intervals to the peripheral edge sides of the outer surface 12 from the well region 37.

The plurality of field regions 38 are formed in band shapes extending along the active region 9 in plan view. The plurality of field regions 38 each have portions extending in a band shape in the first direction X and portions extending in a band shape in the second direction Y. In this embodiment, the plurality of field regions 38 are formed in annular shapes (specifically, quadrilateral annular shapes) surrounding the active region 9 (that is, the plurality of column regions 21) in plan view.

The plurality of field regions 38 are formed inside the semiconductor layer 7 at intervals to the outer surface 12 side from the lower end of the semiconductor layer 7 and form pn junction portions with the semiconductor layer 7. The plurality of field regions 38 preferably have bottom portions positioned at the outer surface 12 side with respect to an intermediate portion of the semiconductor layer 7 in a thickness range thereof.

In this embodiment, the plurality of field regions 38 are formed at intervals to the peripheral edge sides of the chip 2 from the plurality of electric field relaxation structures 21. Therefore, the plurality of field regions 38 do not face the plurality of electric field relaxation structures 21 in the vertical direction Z. The plurality of field regions 38 are positioned further to the second principal surface 4 side of the semiconductor layer 7 than the bottom walls of the trench structures 16.

The bottom portions of the plurality of field regions 38 may be positioned further to the first principal surface 3 side of the semiconductor layer 7 than depth positions of the bottom portions of the plurality of electric field relaxation structures 21. As a matter of course, the bottom portions of the plurality of field regions 38 may be positioned further to the second principal surface 4 side of the semiconductor layer 7 than the depth positions of the bottom portions of the plurality of electric field relaxation structures 21.

The plurality of field regions 38 may have a p-type impurity concentration of not less than 1×10¹⁵ cm⁻³ and not more than 1×10¹⁸ cm⁻³ as a peak value. The p-type impurity concentration of the field region 38 may be substantially equal to the p-type impurity concentration of the body region 15. The p-type impurity concentration of the plurality of field regions 38 may be higher than the p-type impurity concentration of the body region 15. The p-type impurity concentration of the plurality of field regions 38 may be lower than the p-type impurity concentration of the body region 15.

The p-type impurity concentration of the plurality of field regions 38 is preferably adjusted by at least one type of trivalent element. The trivalent element of the field region 38 may be the same type as the trivalent element of the electric field relaxation structure 21, or may be a type different from the trivalent element of the electric field relaxation structure 21. The trivalent element of the field region 38 may be at least one type among boron, aluminum, gallium, and indium.

The plurality of field regions 38 preferably have a width different from the relaxation width WR of the electric field relaxation structures 21. That is, an electric field relaxation effect by the plurality of field regions 38 is preferably adjusted separately from the plurality of electric field relaxation structures 21. The width of the plurality of field regions 38 is particularly preferably smaller than the relaxation width WR As a matter of course, the width of the plurality of field regions 38 may be larger than the relaxation width WR. Also, the width of the plurality of field regions 38 may be substantially equal to the relaxation width WR

The plurality of field regions 38 are preferably formed at a pitch different from the relaxation pitch PR of the electric field relaxation structures 21. The pitch of the plurality of field regions 38 is particularly preferably smaller than the relaxation pitch PR. The pitch of the plurality of field regions 38 may be larger than the relaxation pitch PR. The pitch of the plurality of field regions 38 may be substantially equal to the relaxation pitch PR.

The semiconductor device 1 includes an interlayer insulating film 39 that covers the first principal surface 3. The interlayer insulating film 39 may be referred to as an “insulating film,” an “interlayer film,” an “intermediate insulating film,” etc. In this embodiment, the interlayer insulating film 39 has a laminated structure including a first insulating film 40 and a second insulating film 41. The first insulating film 40 may include at least one among a silicon oxide film, a silicon nitride film, and a silicon oxynitride film. The first insulating film 40 particularly preferably includes the silicon oxide film constituted of the oxide of the chip 2 (the semiconductor layer 7).

The first insulating film 40 selectively covers the first principal surface 3 in the active region 9 and the outer peripheral region 10. Specifically, the first insulating film 40 selectively covers the active surface 11, the outer surface 12, and the first to fourth connecting surfaces 13A to 13D. On the active surface 11, first insulating film 40 is connected to the insulating film 18 on the active surface and exposes the embedded electrode 19.

On the outer surface 12, the first insulating film 40 covers the well region 37 and the plurality of field regions 38. In this embodiment, the first insulating film 40 is continuous to the first to fourth side surfaces 5A to 5D. As a matter of course, the first insulating film 40 may instead be formed at intervals inward from the peripheral edges of the outer surface 12 and expose the semiconductor layer 7 from peripheral edge portions of the outer surface 12. On the first to fourth connecting surfaces 13A to 13D, the first insulating film 40 covers the body region 15 and the well region 37.

The second insulating film 41 is laminated on the first insulating film 40. The second insulating film 41 may include at least one among a silicon oxide film, a silicon nitride film, and a silicon oxynitride film. The interlayer insulating film 39 preferably includes a silicon oxide film. The second insulating film 41 covers the first principal surface 3 with the first insulating film 40 interposed therebetween in the active region 9 and the outer peripheral region 10. Specifically, the second insulating film 41 selectively covers the active surface 11, the outer surface 12, and the first to fourth connecting surfaces 13A to 13D with the first insulating film 40 interposed therebetween.

In the active region 9, the second insulating film 41 covers the plurality of trench structures 16 (the embedded electrodes 19). In the outer peripheral region 10, the second insulating film 41 covers the well region 37 and the plurality of field regions 38 with the first insulating film 40 interposed therebetween. In this embodiment, the second insulating film 41 is continuous to the first to fourth side surfaces 5A to 5D. As a matter of course, the second insulating film 41 may instead be formed at intervals inward from the peripheral edges of the outer surface 12 and, together with the first insulating film 40, expose the peripheral edge portions of the first principal surface 3.

The semiconductor device 1 includes a plurality of contact openings 42 formed in the interlayer insulating film 39. The plurality of contact openings 42 include the plurality of contact openings 42 (not shown) that expose the plurality of trench structures 16 (the embedded electrodes 19) and the plurality of contact openings 42 that expose the plurality of source regions 33. The plurality of contact openings 42 for the source regions 33 are formed in regions between the plurality of trench structures 16 that are mutually adjacent and expose the plurality of source regions 33 and the plurality of contact regions 34.

The semiconductor device 1 includes a side wall structure 43 that is arranged in the interlayer insulating film 39 such as to cover at least one of the first to fourth connecting surfaces 13A to 13D. The side wall structure 43 is arranged on the first insulating film 40 and is covered with the second insulating film 41. The side wall structure 43 moderates a level difference formed between the active surface 11 and the outer surface 12.

The side wall structure 43 is formed in a band shape extending along at least one of the first to fourth connecting surfaces 13A to 13D. In this embodiment, the side wall structure 43 is formed in an annular shape (specifically, a quadrilateral annular shape) extending along the first to fourth connecting surfaces 13A to 13D such as to surround the active surface 11 in plan view.

The side wall structure 43 may have a portion extending in a film shape along the outer surface 12 and a portion extending in a film shape along the first to fourth connecting surfaces 13A to 13D. In this embodiment, the side wall structure 43 is formed at an interval from the innermost field region 38 toward the active surface 11 and faces the well region 37 with the first insulating film 40 interposed therebetween in the horizontal directions and the vertical direction Z. The side wall structure 43 may face the body region 15 with the first insulating film 40 interposed therebetween.

With reference to FIG. 1, the semiconductor device 1 includes a gate pad 44 arranged on the interlayer insulating film 39. The gate pad 44 is an electrode to which the gate potential is applied from an exterior. The gate pad 44 may be referred to as a “gate pad electrode,” a “first pad electrode,” etc. The gate pad 44 may have a laminated structure that includes a Ti-based metal film and an Al-based metal film that are laminated in that order from the interlayer insulating film 39 side.

In this embodiment, the gate pad 44 is arranged on a portion of the interlayer insulating film 39 that covers the active region 9. Specifically, the gate pad 44 is arranged on the active surface 11 at an interval from the outer surface 12 in plan view. The gate pad 44 is arranged in a region adjacent to a central portion of one side (in this embodiment, the second connecting surface 13B) of the active surface 11 in plan view.

As a matter of course, the gate pad 44 may be arranged in a region along any of central portions of the first to fourth connecting surfaces 13A to 13D. As a matter of course, the gate pad 44 may be arranged in an arbitrary corner portion of the active surface 11 in plan view. Also, the gate pad 44 may be arranged at a central portion of the active surface 11 in plan view. In this embodiment, the gate pad 44 is formed in a quadrilateral shape in plan view.

The semiconductor device 1 includes at least one (in this embodiment, a plurality) of gate wirings 45 that is led out onto the interlayer insulating film 39 from the gate pad 44. The gate wiring 45 may be referred to as a “wiring,” a “wiring electrode,” etc. In this embodiment, the plurality of gate wirings 45 are arranged on the active surface 11 at intervals from the outer surface 12 in plan view.

The plurality of gate wirings 45 may have a laminated structure that includes a Ti-based metal film and an Al-based metal film that are laminated in that order from the interlayer insulating film 39 side. In this embodiment, the plurality of gate wirings 45 include a first gate wiring 45A and a second gate wiring 45B.

The first gate wiring 45A is led out toward the first connecting surface 13A side from the gate pad 44 and extends in a line shape along the peripheral edge of the active surface 11 such as to intersect (specifically, be orthogonal to) portions (specifically, one end portions) of the plurality of trench structures 16. The first gate wiring 45A penetrates through the interlayer insulating film 39 via the plurality of contact openings 42 and is electrically connected to the one end portions of the plurality of trench structures 16.

The second gate wiring 45B is led out toward the third connecting surface 13C side from the gate pad 44 and extends in a line shape along the peripheral edge of the active surface 11 such as to intersect (specifically, be orthogonal to) portions (specifically, the other end portions) of the plurality of trench structures 16. The second gate wiring 45B penetrates through the interlayer insulating film 39 via the plurality of contact openings 42 and is electrically connected to the other end portions of the plurality of trench structures 16.

The semiconductor device 1 includes a source pad 46 arranged on the interlayer insulating film 39 at intervals from the gate pad 44 and the gate wirings 45. The source pad 46 is an electrode to which a source potential is applied from an exterior. The source pad 46 may be referred to as a “source pad electrode,” a “second pad electrode,” etc. The source pad 46 may have a laminated structure that includes a Ti-based metal film and an Al-based metal film that are laminated in that order from the interlayer insulating film 39 side.

In this embodiment, the source pad 46 is arranged on the active surface 11 at an interval from the outer surface 12 in plan view. In this embodiment, the source pad 46 is formed in a polygonal shape having a recess portion that is recessed along the gate pad 44 in plan view. As a matter of course, the source pad 46 may instead be formed in a quadrilateral shape in plan view.

The source pad 46 penetrates the interlayer insulating film 39 via the plurality of contact openings 42 and is electrically connected to the body regions 15, the plurality of source regions 33, and the plurality of contact regions 34. That is, the source pad 46 is electrically connected to the plurality of electric field relaxation structures 21 via the body region 15.

The semiconductor device 1 includes a drain pad 47 that covers the second principal surface 4. The drain pad 47 is an electrode to which a drain potential is applied from an exterior. The drain pad 47 may be referred to as a “drain pad electrode,” a “third pad electrode,” etc. The drain pad 47 forms an ohmic contact with the base layer 6 exposed from the second principal surface 4.

That is, the drain pad 47 is electrically connected to the plurality of drift regions 8 via the base layer 6. The drain pad 47 may cover an entirety of the second principal surface 4 such as to be continuous to the peripheral edges (the first to fourth side surfaces 5A to 5D) of the chip 2. The drain pad 47 may cover the second principal surface 4 at intervals inward from the peripheral edges of the chip 2 such as to expose the peripheral edge portions of the chip 2.

A breakdown voltage applicable between the source pad 46 and the drain pad 47 (between the first principal surface 3 and the second principal surface 4) may be not less than 500 V and not more than 3000 V. The breakdown voltage may have a value belonging to any one range among not less than 500 V and not more than 1000 V, not less than 1000 V and not more than 1500 V, not less than 1500 V and not more than 2000 V, not less than 2000 V and not more than 2500 V, and not less than 2500 V and not more than 3000 V.

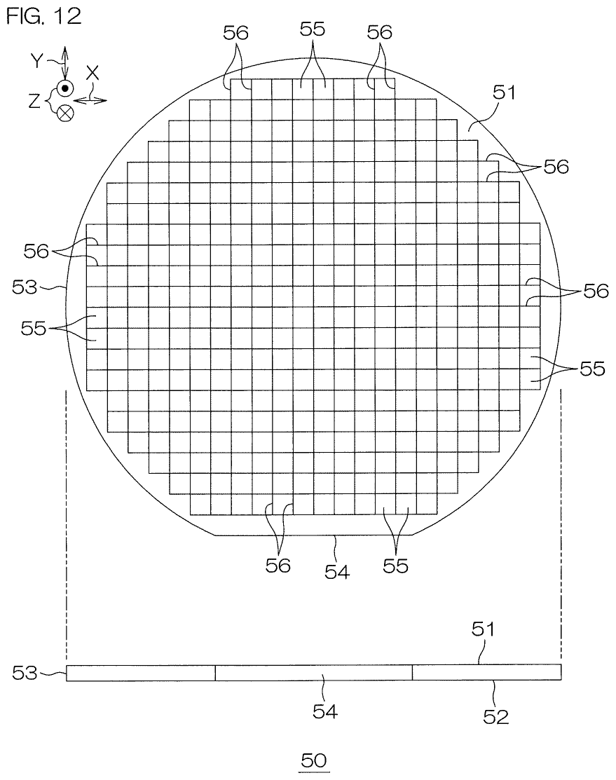

FIG. 12 is a schematic view showing a wafer 50 used in manufacture of the semiconductor device 1. The wafer 50 is a base material of the base layer 6 and contains an SiC monocrystal. The wafer 50 is formed in a flat disk shape. As a matter of course, the wafer 50 may be formed in a flat rectangular parallelepiped shape instead. The wafer 50 has a first wafer principal surface 51 on one side, a second wafer principal surface 52 on the other side, and a wafer side surface 53 connecting the first wafer principal surface 51 and the second wafer principal surface 52.

The first wafer principal surface 51 corresponds to the upper end of the base layer 6, and the second wafer principal surface 52 corresponds to a lower end of the base layer 6. The first wafer principal surface 51 and the second wafer principal surface 52 are formed by c-planes of the SiC monocrystal. The first wafer principal surface 51 is formed by a silicon plane of the SiC monocrystal, and the second wafer principal surface 52 is formed by a carbon plane of the SiC monocrystal. The wafer 50 (the first wafer principal surface 51 and the second wafer principal surface 52) has the off direction Do and the off angle θo described above.

The wafer 50 has, on the wafer side surface 53, a mark 54 that indicates a crystal orientation of the SiC monocrystal. The mark 54 may include either or both of an orientation flat and an orientation notch. The orientation flat is constituted of a notched portion that is notched rectilinearly in plan view. The orientation notch is constituted of a notched portion that is notched in a recessed shape (for example, a tapered shape) toward a central portion of the first wafer principal surface 51 in plan view.

The mark 54 may include either or both of a first orientation flat that extends in the m-axis direction and a second orientation flat that extends in the a-axis direction. The mark 54 may include either or both of an orientation notch that is recessed in the m-axis direction and an orientation notch flat that is recessed in the a-axis direction. In FIG. 12, the orientation flat that extends in the m-axis direction (the first direction X) in plan view is shown.

For example, a plurality of device regions 55 and a plurality of intended cutting lines 56 are set by alignment marks, etc., in the wafer 50. Each device region 55 is a region corresponding to the semiconductor device 1. The plurality of device regions 55 are each set in a quadrilateral shape in plan view.

In this embodiment, the plurality of device regions 55 are set in a matrix along the first direction X and the second direction Y. The plurality of device regions 55 are each set at intervals inward from a peripheral edge of the first wafer principal surface 51 in plan view. The plurality of intended cutting lines 56 are set in a lattice extending along the first direction X and the second direction Y such as to demarcate the plurality of device regions 55.

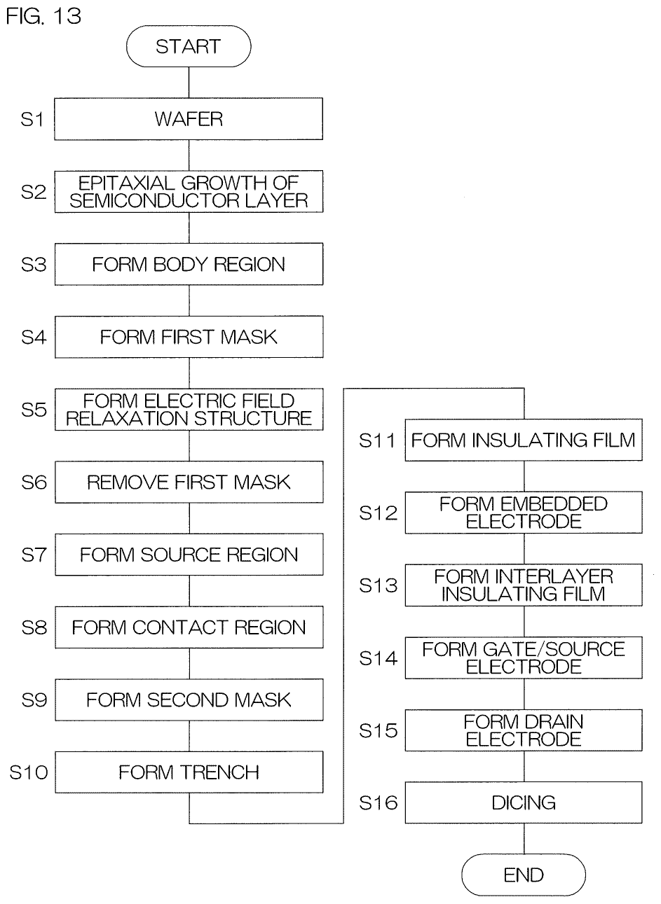

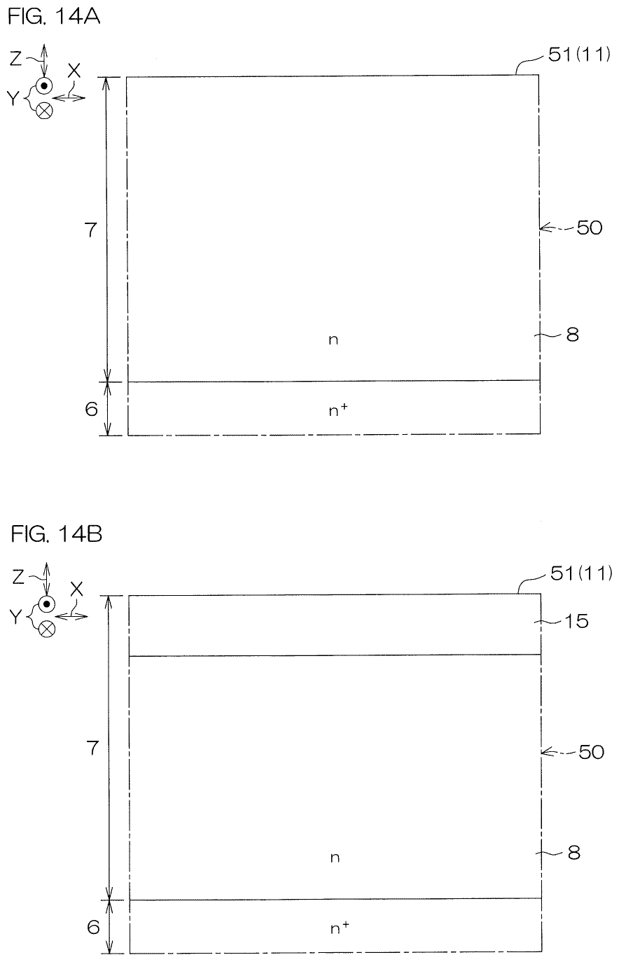

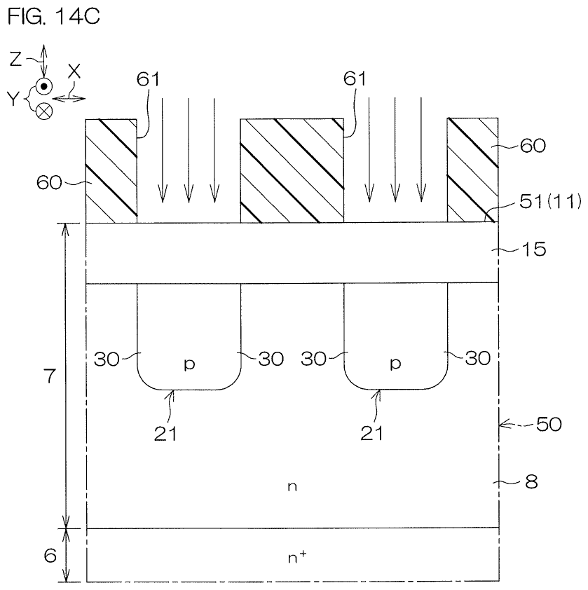

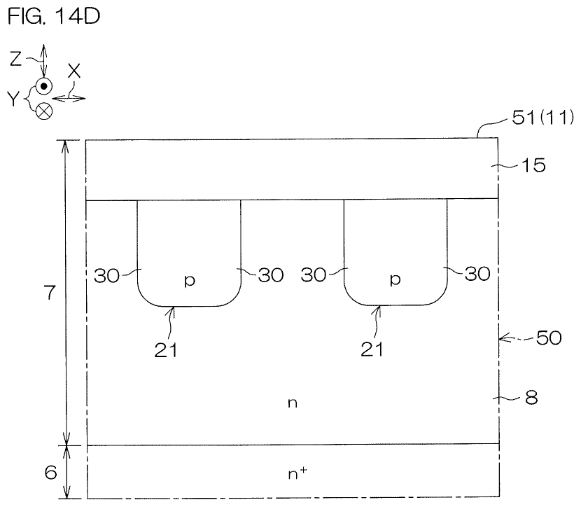

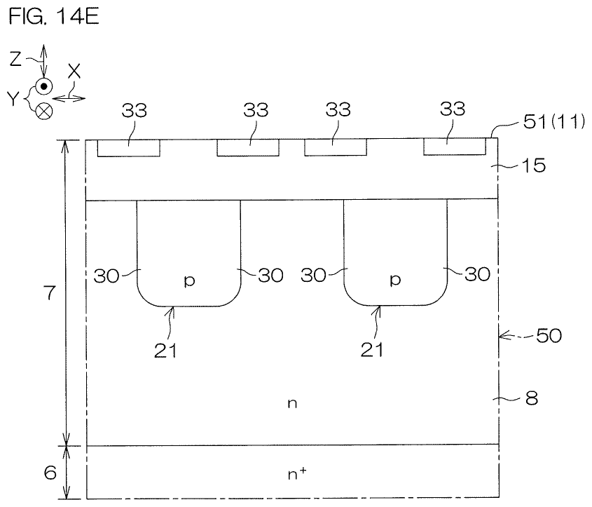

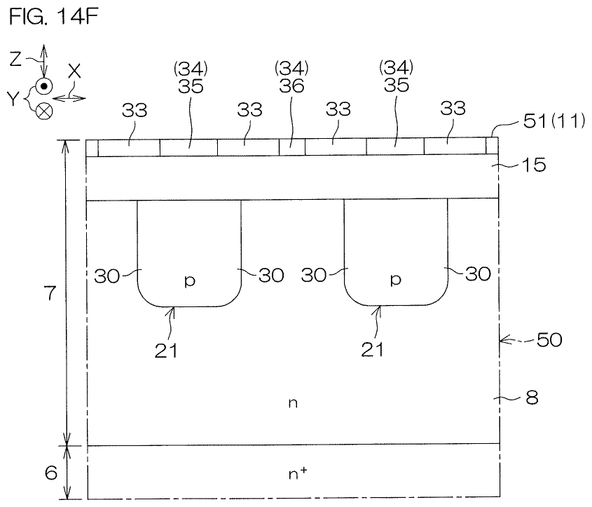

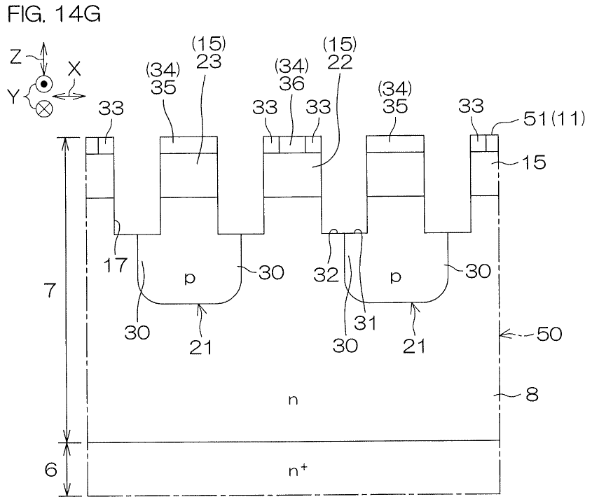

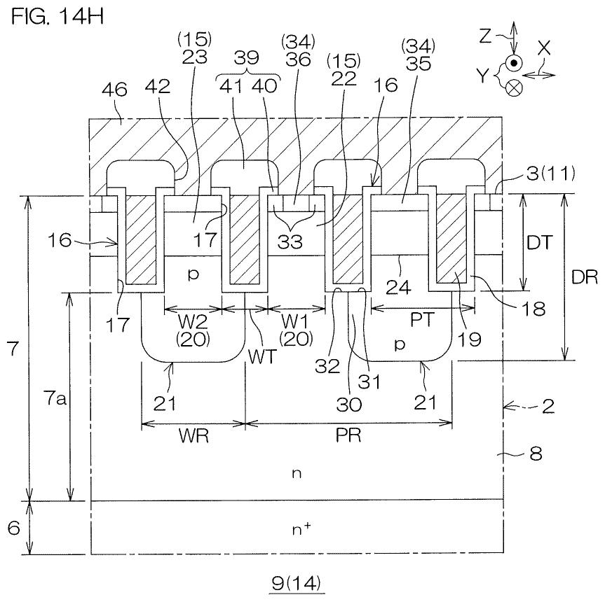

FIG. 13 is a flowchart showing a manufacturing method example of the semiconductor device 1. FIG. 14A to FIG. 14H are sectional views showing the manufacturing method example of the semiconductor device 1. FIG. 14A to FIG. 14H are sectional views corresponding to FIG. 7.

First, with reference to FIG. 14A, a preparation step of the wafer 50 described above is performed (step S1 in FIG. 13). Next, a forming step of the semiconductor layer 7 is performed (step S2 in FIG. 13). The semiconductor layer 7 is formed by an epitaxial growth method with the first wafer principal surface 51 (the wafer 50) as a starting point.

Next, with reference to FIG. 14B, a forming step of the body region 15 is performed (step S3 in FIG. 13). In the forming step of the body region 15, a p-type impurity is introduced into an entirety of the semiconductor layer 7. The body region 15 are thereby be formed in an entirety of the surface layer portion of the semiconductor layer 7.

Next, with reference to FIG. 14C, a forming step of a first mask 60 having a predetermined pattern is performed (step S4 in FIG. 13). The first mask 60 is preferably an inorganic mask (a hard mask). The first mask 60 is arranged on the upper end of the semiconductor layer 7 and has a plurality of first openings 61 that expose regions in which the plurality of electric field relaxation structures 21 are to be formed. Next, a forming step of the plurality of electric field relaxation structures 21 is performed (step S5 in FIG. 13). In the forming step of the electric field relaxation structures 21, the p-type impurity is selectively introduced into the semiconductor layer 7 via the first mask 60. The electric field relaxation structures 21 connected to the lower portion of the body region 15 is thereby formed.

As a forming method of the electric field relaxation structures 21, various ion implantation methods can be applied. For example, the electric field relaxation structures 21 may be formed by a channeling ion implantation method. The channeling implantation step is performed based on the data (the information) on the off angle θo. In the channeling implantation step, the electric field relaxation structures 21 can be selectively and easily formed at a deep position of the semiconductor layer 7. In a case where the electric field relaxation structures 21 are formed by the channeling ion implantation method, the electric field relaxation structures 21 may be formed before the body region 15 is formed.

Next, with reference to FIG. 14D, the first mask 60 is removed (step S6 in FIG. 13).

Next, with reference to FIG. 14E, a forming step of the plurality of source regions 33 is performed (step S7 in FIG. 13). The plurality of source regions 33 are formed by introducing an n-type impurity into the surface layer portion of the semiconductor layer 7 by an ion implantation method performed via a mask (not shown) having a predetermined layout.

Next, with reference to FIG. 14F, a forming step of the plurality of contact regions 34 is performed (step S8 in FIG. 13). The plurality of contact regions 34 are formed by introducing the p-type impurity into the surface layer portion of the semiconductor layer 7 by the ion implantation method performed via a mask (not shown) having a predetermined layout. At this time, the first contact region 35 and the second contact region 36 are formed physically independently of each other. The forming step of the contact regions 34 may be performed prior to the forming step of the source regions 33.

Next, with reference to FIG. 14G, a forming step of the plurality of trenches 17 is performed. First, a second mask (not shown) having a predetermined pattern is formed (step S9 in FIG. 13). The second mask is preferably an inorganic mask (a hard mask). Next, unnecessary portions of the semiconductor layer 7 are removed by an etching method via the second mask. The etching method may be either or both of a wet etching method and a dry etching method. The etching method is preferably an RIE (reactive ion etching) method. The plurality of trenches 17 are thereby formed at the upper end of the semiconductor layer 7 (step S10 in FIG. 13). Also, the active surface 11, the outer surface 12, and the first to fourth connecting surfaces 13A to 13D are formed at the upper end of the semiconductor layer 7. After the forming step of the plurality of trenches 17, the second mask is removed.

Next, with reference to FIG. 14H, a forming step of the insulating films 18 is performed (step S11 in FIG. 13). The forming step of the insulating films 18 serves in common as a forming step of the first insulating film 40. The insulating films 18 may be formed by either or both of a CVD (chemical vapor deposition) method and an oxidation treatment method. The insulating films 18 and the first insulating film 40 are typically formed by a thermal oxidation treatment method. The insulating films 18 are formed in a film shape on the wall surfaces of the plurality of trenches 17, and the first insulating film 40 is formed in a film shape in a region of the upper end of the semiconductor layer 7 outside the plurality of trenches 17.

Next, a forming step of the embedded electrodes 19 is performed (step S12 in FIG. 13). This step includes a step of forming a base electrode film on the insulating films 18. In this embodiment, the base electrode film contains a conductive polysilicon. The base electrode film backfills the plurality of trenches 17 and covers the upper end of the semiconductor layer 7. The base electrode film may be formed by the CVD method. Next, unnecessary portions of the embedded electrodes 19 are removed by the etching method. The unnecessary portions of the embedded electrodes 19 are removed until the insulating films 18 are exposed. The etching method may be either or both of a wet etching method and a dry etching method. Thereby, the plurality of embedded electrodes 19 are respectively embedded inside the plurality of trenches 17 and the plurality of trench structures 16 are formed.

Next, a forming step of the interlayer insulating film 39 (the second insulating film 41) is performed (step S13 in FIG. 13). The interlayer insulating film 39 may be formed by the CVD method. The plurality of contact openings 42 having a predetermined layout are formed in the interlayer insulating film 39 by an etching method performed via a mask (not shown) having the predetermined layout.

Next, a forming step of the gate pad 44, the gate wirings 45, and the source pad 46 is performed (step S14 in FIG. 13) The gate pad 44, the gate wirings 45, and the source pad 46 are formed by depositing a metal film on the interlayer insulating film 39 by the sputtering method and thereafter forming to a predetermined layout by the etching method performed via a mask (not shown) having the predetermined layout.

Next, a forming step of the drain pad 47 is performed (step S15 in FIG. 13). The drain pad 47 is formed by depositing a metal film on the second wafer principal surface 52 by the sputtering method. Thereafter, the wafer 50 is cut along the plurality of intended cutting lines 56 (step S16 in FIG. 13). Through steps including the above, a plurality of semiconductor devices 1 are manufactured from the single wafer 50.

As described above, since the electric field relaxation structure 21 is formed on the bottom wall of the trench 17, it is possible to relax concentration of electric fields on the bottom wall of the trench 17 of the trench gate structure according to the MISFET (metal insulator semiconductor field effect transistor).

The electric field relaxation structure 21 is not formed on a one-to-one correspondence with respect to each trench 17 and straddles the bottom walls of the plurality of trenches 17. In this embodiment, one of the electric field relaxation structures 21 straddles the bottom walls of the two trenches 17 that are mutually adjacent. A dimension (for example, the relaxation width WR, the relaxation pitch PR, etc.) of the electric field relaxation structure 21 can thereby be set by independent design without depending on the width WT of each trench 17 and the pitch PT of the plurality of trenches 17. As a result, it is possible to easily manufacture the electric field relaxation structures 21 by designing appropriately.

Therefore, even in design conditions in which the trench pitch PT of patterns of the plurality of trench structures 16 is narrow due to miniaturization, a sufficient processing dimension margin can be obtained by using a pattern of the electric field relaxation structure 21 having the width WR wider than the trench pitch PT. For example, in a case where the trench pitch PT=the relaxation pitch PR, when a mask pattern is misaligned even slightly at the time of forming the electric field relaxation structures 21, the electric field relaxation structures 21 are formed separate from the trenches 17 in the horizontal directions, the bottom walls of the trenches 17 are not covered with the electric field relaxation structure 21, and there is a concern about a decrease in breakdown voltage. However, according to the semiconductor device 1 of this embodiment, even when the mask pattern is misaligned at the time of forming the electric field relaxation structures 21, the electric field relaxation structures 21 are formed to have a wide width in the horizontal directions, the bottom walls of the trenches 17 can therefore be reliably covered with the electric field relaxation structures 21.

Also, in the steps in FIG. 14C and FIG. 14D, since the electric field relaxation structures 21 need to be formed deeper than the body region 15, the first mask 60 needs to be formed relatively thick. This is because, while the ions have to be accelerated with high energy in order to implant ions into a deep position, the accelerated ions are prevented from penetrating the first mask 60 and being implanted. Therefore, an aspect ratio of the first mask 60 tends to increase as the width of the first mask 60 becomes narrower due to miniaturization. When the aspect ratio is high, the durability of the first mask 60 against an external force decreases, and the first mask 60 is likely to collapse or tilt due to own weight or an external force. On the other hand, if the dimension (for example, the relaxation width WR, the relaxation pitch PR, etc.) of the electric field relaxation structures 21 can be designed independently of the dimension of the trench 17, the aspect ratio of the first mask 60 can be reduced to be low. As a result, even when the trenches 17 are miniaturized, the electric field relaxation structures 21 can be accurately formed.

Also, a portion of the body region 15 which is physically and electrically integral with the electric field relaxation structure 21 is covered with a portion of the second conductivity type (the body region 15 and the electric field relaxation structure 21) from the side wall to the bottom wall of the trench 17. Since a range in which an inversion layer is to be formed along an inner wall of the trench 17 becomes prolonged, a voltage (a threshold voltage) necessary for channel formation is likely to be selectively high as compared with that of the channel portion 22. Thus, a variation in a threshold voltage of the semiconductor device 1 can be reduced by forming, as the non-channel portion 23, a portion of the body region 15 which is physically and electrically integral with the electric field relaxation structure 21.

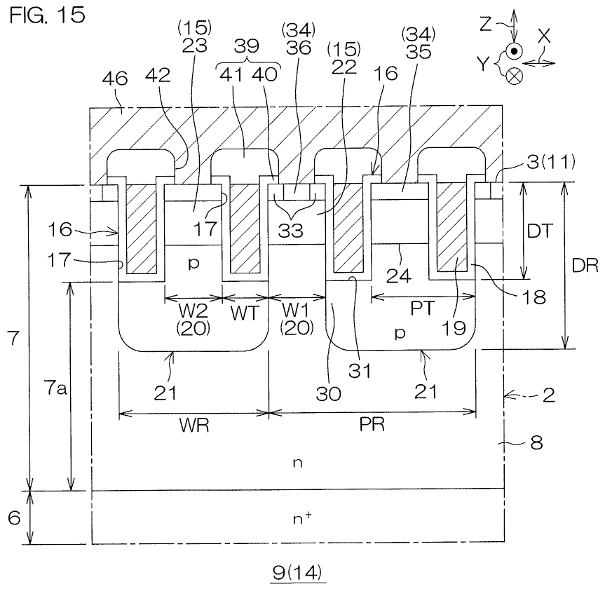

FIG. 15 to FIG. 20 are views showing first to sixth modification examples of the semiconductor device 1. Next, the modification examples of the semiconductor device 1 shall be described with reference to FIG. 15 to FIG. 20.

With reference to FIG. 15, each electric field relaxation structure 21 may have the end portion 30 at the wall surface (the side wall) of the trench 17 on the channel portion 22 side in the width direction of the trench 17. For example, in sectional view, the wall surface (the side wall) of the trench 17 and the end portion 30 of the electric field relaxation structure 21 may continue in a rectilinear shape in the vertical direction Z.

According to this arrangement, it is possible to further relax the concentration of the electric fields on the bottom wall of the trench 17 since the bottom wall of the trench 17 is completely covered with the electric field relaxation structure 21. However, as compared with the structure of FIG. 7 to FIG. 9, the electric field relaxation structure 21 becomes an obstacle and it becomes difficult to form a current path in a portion of the bottom wall of the trench 17 on the channel portion 22 side. Therefore, in comparison with FIG. 7 to FIG. 9, there is a possibility that the on-resistance increases. In other words, in the structure of FIG. 7 to FIG. 9, relaxation of the concentration of the electric fields on the bottom wall of the trench 17 and a reduction of the on-resistance can be achieved in a well-balanced manner.

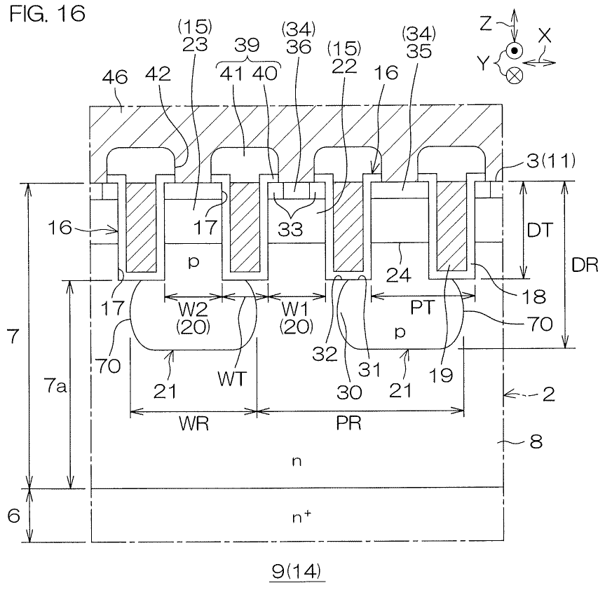

With reference to FIG. 16, the end portion 30 of each electric field relaxation structure 21 do not have to have a planar shape parallel or substantially parallel to the vertical direction Z from the bottom wall of the trench 17, and may have a curved surface shape bulging toward the channel portion 22 side in the horizontal direction (at least one of the first direction X and the second direction Y).

In this case, a top portion 70 of the curved surface of the end portion 30 of each electric field relaxation structure 21 is preferably located further inward (the non-channel portion 23 side) than the wall surface (the side wall) of the trench 17 on the channel portion 22 side. In other words, the end portion 30 of a curved surface shape is preferably formed by retreating further inward the non-channel portion 23 side than the wall surface (the side wall) of the trench 17 on the channel portion 22 side in the horizontal direction. A current path can thereby be sufficiently secured along the wall surfaces (the side wall and the bottom wall) of the trench 17 on the channel portion 22 side since a portion of the bottom wall of the trench 17 on the channel portion 22 side is covered with the drift region 8. As a result, the on-resistance can be reduced.

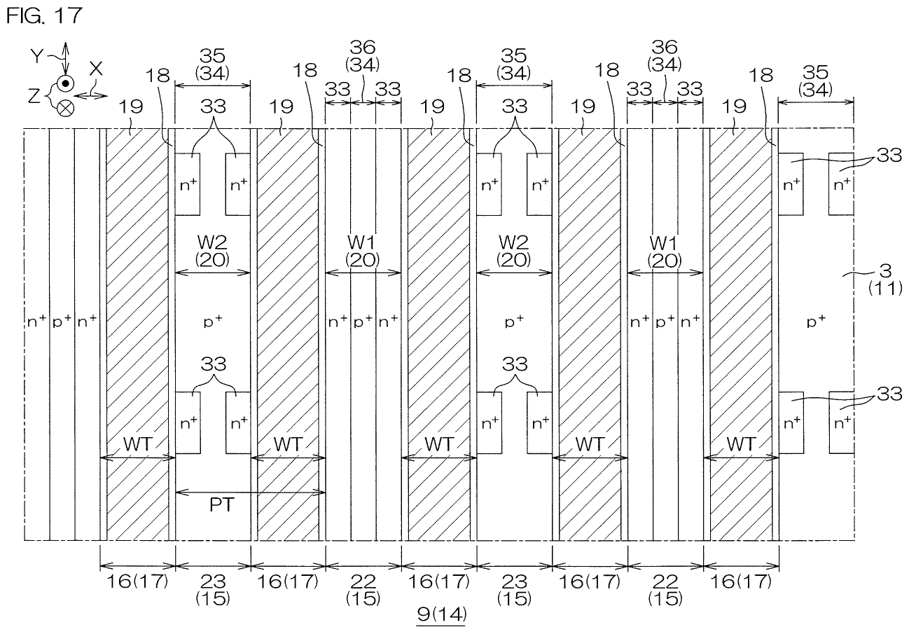

With reference to FIG. 17, the source region 33 may be formed in a part of the non-channel portion 23. For example, the plurality of source regions 33 may be formed at intervals in the extension direction of the corresponding trench structures 16 in plan view.

In the non-channel portion 23, since the electric field relaxation structures 21 having a higher p-type impurity concentration higher than that of the body region 15 are formed, a channel (an inversion layer) is less likely to be formed in the non-channel portion than in the channel portion 22. Although under such conditions, a function of forming a channel can also be imparted to the non-channel portion 23 by forming the source regions 33 in the non-channel portion 23.

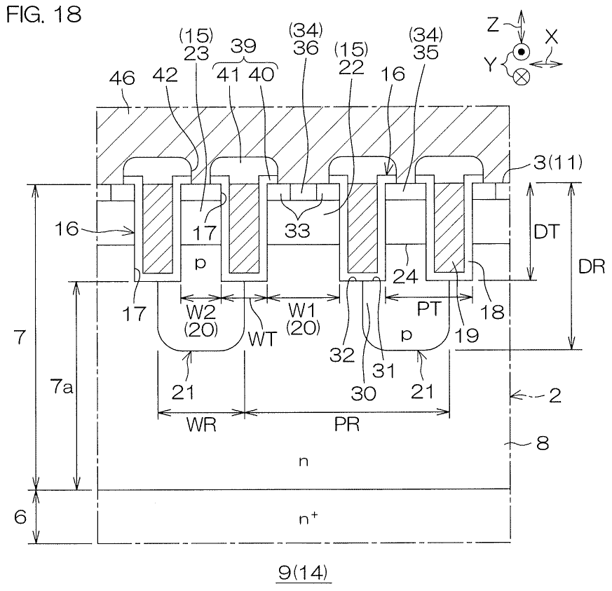

With reference to FIG. 18, the first width W1 of the mesa portion 20 forming the channel portion 22 may be wider than the second width W2 of the mesa portion 20 forming the non-channel portion 23.

According to this arrangement, it is possible to improve a channel density since a ratio of the channel portion 22 with respect to the entire chip 2 can be increased by making the first width W1 wider than the second width W2.

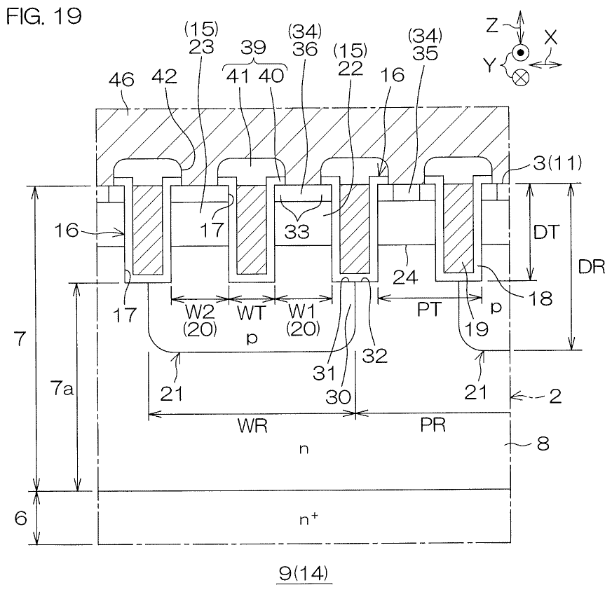

With reference to FIG. 19, the plurality of electric field relaxation structures 21 may straddle the bottom walls of three or more consecutive trenches 17 in the first direction X. In this case, each electric field relaxation structure 21 straddles the bottom walls of the trenches 17 at both ends among the three or more consecutive trenches 17 in the first direction X. In FIG. 19, each electric field relaxation structure 21 straddles the bottom walls of the three consecutive trenches 17 in the first direction X.

The bottom wall of the center trench 17 among the three trenches 17 is completely covered with the electric field relaxation structure 21. The body region 15 on both sides of the center trench 17 in the first direction X is the non-channel portions 23 connected to the electric field relaxation structure 21. The bottom walls of the two trenches 17 at both ends among the three trenches 17 are partially covered with the electric field relaxation structure 21. The bottom walls of the two trenches 17 at both ends to thereby have the first portion 31 covered with the electric field relaxation structure 21 and the second portion 32 covered with the semiconductor layer 7 (the drift region 8).

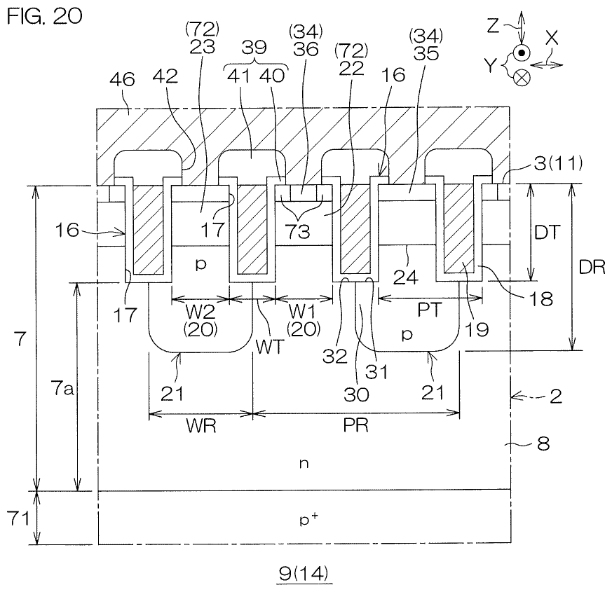

With reference to FIG. 20, an element structure of the semiconductor device 1 may be an IGBT (insulated gate bipolar transistor) structure different from the MISFET structure of FIG. 7 to FIG. 9. In this case, a collector region 71 of the p-type may be formed instead of the base layer 6. Also, a base region 72 of the p-type may be formed by the body region 15, and an emitter region 73 of the n-type may be formed by the source region 33.

Also in this arrangement, the electric field relaxation structure 21 straddles the bottom walls of the plurality of trenches 17. Therefore, it is possible to relax the concentration of the electric fields on the bottom wall of the trench 17 of the trench gate structure according to the IGBT.

Although the preferred embodiment of the present disclosure has been described above, the present disclosure can be implemented in other modes.

For example, with each preferred embodiment described above, the base layer 6 and the semiconductor layer 7 that each include the SiC monocrystal are adopted. However, at least one or all of the base layer 6 and the semiconductor layer 7 may include a monocrystal of a wide bandgap semiconductor other than the SiC monocrystal.

The wide bandgap semiconductor is a semiconductor that has a greater bandgap than the bandgap of silicon. As examples of a monocrystal of a wide bandgap semiconductor, silicon carbide (SiC), gallium nitride (GaN), diamond (C), gallium oxide (Ga₂O₃), etc., can be cited. The base layer 6 and the semiconductor layer 7 may be constituted of monocrystals of the same type or may be constituted of monocrystals of different types. Also, at least one or all of the base layer 6 and the semiconductor layer 7 may be constituted of silicon (Si).

Hereinafter, examples of features extracted from this Description and the attached drawings shall be described. Hereinafter, the alphanumeric characters, etc., in parentheses represent the corresponding components, etc., in the preferred embodiment described above, but are not intended to limit the scope of each clause to the preferred embodiment. The “semiconductor device” in the following clauses may be replaced with an “SiC semiconductor device,” a “wide bandgap semiconductor device,” “a semiconductor switching device,” a “semiconductor rectifier,” a “MISFET device,” an “IGBT device,” a “diode device,” etc., as needed.

### [Clause 1-1]

A Semiconductor Device (1) Including:
a chip (2) that has a first principal surface (3) and a second principal surface (4) on an opposite side thereto;
a first impurity region (7, 8) of a first conductivity type that is formed in a surface layer portion of the first principal surface (3);
a second impurity region (15, 72) of a second conductivity type that is formed in a surface layer portion of the first impurity region (7, 8);
a third impurity region (33, 73) of the first conductivity type that is formed in a surface layer portion of the second impurity region (15, 72);
a plurality of trenches (17) that reach the first impurity region (7, 8) through the third impurity region (33, 73) and the second impurity region (15, 72) from the first principal surface (3); and
an electric field relaxation structure (21) of the second conductivity type that is formed integrally with the second impurity region (15, 72) and straddles bottom walls of the plurality of trenches (17).

According to this arrangement, it is possible to relax concentration of the electric fields on the bottom wall of the trench (17) since the electric field relaxation structure (21) is formed on the bottom wall of the trench (17). The electric field relaxation structure (21) is not formed on a one-to-one correspondence with respect to each trench (17) and straddles the bottom walls of the plurality of trenches (17). A dimension of the electric field relaxation structure (21) can thereby be set by independent design without depending on the width of each trench (17) and the pitch of the plurality of trenches (17). As a result, it is possible to easily manufacture the electric field relaxation structure (21) by designing appropriately. For example, even in design conditions in which the pitch of patterns of the plurality of trenches (17) is narrow due to miniaturization, a sufficient processing dimension margin can be obtained by using a pattern of the electric field relaxation structure (21) having the width wider than the pitch of the trenches (17).

### [Clause 1-2]

The semiconductor device (1) according to Clause 1-1, wherein the second impurity region (15, 72) includes a channel portion (22) that is physically and electrically separated from the electric field relaxation structure (21), and in which a channel is formed along the trench (17) adjacent to the channel portion (22), and a non-channel portion (23) which is physically and electrically integral with the electric field relaxation structure (21) and has a bottom wall covered with the electric field relaxation structure (21).

Also, a portion of the second impurity region (15, 72) which is physically and electrically integral with the electric field relaxation structure (21) is covered with a portion of the second conductivity type (the second impurity region (15, 72) and the electric field relaxation structure (21)) from the side wall to the bottom wall of the trench (17). Since a range in which an inversion layer is to be formed along an inner wall of the trench 17 becomes prolonged, a voltage (a threshold voltage) necessary for channel formation is likely to be selectively high in the corresponding portion. Thus, a variation in the threshold voltage can be reduced by forming, as the non-channel portion (23), a portion of the second impurity region (15, 72) which is physically and electrically integral with the electric field relaxation structure (21).

### [Clause 1-3]

The semiconductor device (1) according to Clause 1-2, wherein the channel portion (22) has a width (W1) wider than the non-channel portion (23).

According to this arrangement, it is possible to improve a channel density since a ratio of the channel portion (22) with respect to the entire chip (2) can be increased by making the width (W1) of the channel portion (22) wider than the non-channel portion (23).

### [Clause 1-4]

The semiconductor device (1) according to Clause 1-2 or 1-3, wherein the electric field relaxation structure (21) has an end portion (30) at a central position of the bottom wall of the trench (17) further to the non-channel portion (23) side than a wall surface of the trench (17) on the channel portion (22) side in a width direction of the trench (17).

According to this arrangement, it is possible to sufficiently secure a current path along the wall surface of the trench (17) on the channel portion (22) side since the electric field relaxation structure (21) and the wall surfaces of the trench (17) on the channel portion (22) side are formed at an interval. On-resistance can thereby be reduced.

### [Clause 1-5]

The semiconductor device (1) according to any one of Clauses 1-2 to 1-4, wherein the bottom wall of the trench (17) includes a first portion (31) that is formed on the non-channel portion (23) side in the width direction of the trench (17) and covered with the electric field relaxation structure (21), and a second portion (32) that is formed on the channel portion (22) side with respect to the first portion (31) and covered with the first impurity region (7, 8).

According to this arrangement, it is possible to sufficiently secure the current path along the wall surface of the trench (17) on the channel portion (22) side since the portion of the bottom wall of the trench (17) on the channel portion (22) side is covered with the first impurity region (7, 8) (the first conductivity type). On-resistance can thereby be reduced.

### [Clause 1-6]

The semiconductor device (1) according to any one of Clauses 1-2 to 1-5, wherein
the third impurity region (33, 73) is selectively formed in the channel portion (22), of the channel portion (22) and the non-channel portion (23), and
the semiconductor device (1) further includes a fourth impurity region (34, 35, 36) of the second conductivity type that is formed in the surface layer portion of the second impurity region (15, 72) and has an impurity concentration higher than the second impurity region (15, 72), and
the fourth impurity region (34, 35, 36) includes a first contact region (35) that is formed in the non-channel portion (23).

According to this arrangement, the third impurity region (33, 73) is selectively formed in the channel portion (22), of the channel portion (22) and the non-channel portion (23). On the other hand, in the non-channel portion (23), the third impurity region (33, 73) is not formed, and the first contact region (35) is formed. This enables on-operation to be efficiently performed by dividing a function of the channel portion (22) to form the current path and a function of the non-channel portion (23) to secure electrical contact with the second impurity region (15, 72).

### [Clause 1-7]

The semiconductor device (1) according to Clause 1-6, wherein the fourth impurity region (34, 35, 36) includes a second contact region (36) that, in the channel portion (22), penetrates the third impurity region (33, 73) and is connected to the second impurity region (15, 72).

According to this arrangement, it is possible to secure electrical contact with the second impurity region (15, 72) also in the channel portion (22).

### [Clause 1-8]

The semiconductor device (1) according to Clause 1-7, wherein
the channel portion (22) and the non-channel portion (23) are respectively demarcated by regions sandwiched by the plurality of trenches (17),
the first contact region (35) is formed over an entirety of the first principal surface (3) between the trench (17) on one side and the trench (17) on the other side of the non-channel portion (23), and
the second contact region (36) is formed to be sandwiched between a plurality of the third impurity regions (33, 73) arranged contiguous to both of the trench (17) on one side and the trench (17) on the other side of the channel portion (22).

According to this arrangement, it is possible to form, in the channel portion (22), a channel along the wall surfaces of the trenches (17) on both sides, that is, the trench (17) on one side and the trench (17) on the other side. Since a plurality of current paths can be formed in the one channel portion (22), the on-resistance can be reduced.

### [Clause 1-9]

The semiconductor device (1) according to any one of Clauses 1-1 to 1-8, wherein
the plurality of electric field relaxation structures (21) are arranged at intervals, and
a pitch (PR) of the electric field relaxation structures (21) that are mutually adjacent is not less than twice a pitch (PT) of the trenches (17) that are mutually adjacent.

According to this arrangement, it is possible to provide a relative clearance to a processing dimension margin of the electric field relaxation structure (21) even in a case where a fine pattern of the trench (17) is formed. It is thereby possible to easily manufacture the electric field relaxation structure (21).

### [Clause 1-10]

The semiconductor device (1) according to Clause 1-9, wherein the pitch (PT) of the trenches (17) is not more than 4 μm.

### [Clause 1-11]

The semiconductor device (1) according to Clause 1-9 or 1-10, wherein the pitch (PT) of the trenches (17) is not less than 0.5 μm and not more than 3 μm.

### [Clause 1-12]

The semiconductor device (1) according to any one of Clauses 1-1 to 1-11, wherein a depth (DR) of the electric field relaxation structure (21) is not less than twice a depth (DT) of the trench (17).

### [Clause 1-13]

The semiconductor device (1) according to any one of Clauses 1-1 to 1-12, wherein
the depth (DT) of the trench (17) is not less than 0.5 μm and not more than 1.5 μm, and
the depth (DR) of the electric field relaxation structure (21) is not less than 2 μm and not more than 3 μm.

### [Clause 1-14]

The semiconductor device (1) according to any one of Clauses 1-9 to 1-11, wherein the plurality of electric field relaxation structures (21) include at least one of the electric field relaxation structures (21) that straddles the bottom walls of the two trenches (17) which are mutually adjacent.

### [Clause 1-15]

The semiconductor device (1) according to any one of Clauses 1-9 to 1-11, wherein the plurality of electric field relaxation structures (21) include at least one of the electric field relaxation structures (21) that straddles the bottom walls of the trenches (17) at both ends among the three consecutive trenches (17).

### [Clause 1-16]

The semiconductor device (1) according to any one of Clauses 1-1 to 1-15, including:
a drain region (6) of the first conductivity type that is formed on the second principal surface (4) side with respect to the first impurity region (7, 8);
a body region (15) that is formed by the second impurity region (15, 72);
a source region (33) that is formed by the third impurity region (33, 73); and
a trench gate structure (16) that is formed by the trench (17), an insulating film (18) covering the wall surface of the trench (17), and an embedded electrode (19) embedded in the trench (17).

According to this arrangement, it is possible to easily manufacture a structure capable of relaxing concentration of electric fields on the bottom wall of the trench gate structure (16) according to the MISFET (metal insulator semiconductor field effect transistor).

### [Clause 1-17]

The semiconductor device (1) according to any one of Clauses 1-1 to 1-15, including:
a collector region (71) of the second conductivity type that is formed on the second principal surface (4) side with respect to the first impurity region (7, 8);
a base region (72) that is formed by the second impurity region (15, 72); and
an emitter region (73) that is formed by the third impurity region (33, 73); and
a trench gate structure (16) that is formed by the trench (17), an insulating film (18) covering the wall surface of the trench (17), and an embedded electrode (19) embedded in the trench (17).

According to this arrangement, it is possible to easily manufacture a structure capable of relaxing concentration of electric fields on the bottom wall of the trench gate structure (16) according to an IGBT (insulated gate bipolar transistor).

### [Clause 1-18]

The semiconductor device (1) according to any one of Clauses 1-1 to 1-17, wherein the chip (2) includes an SiC chip (2).

### [Clause 1-19]

The semiconductor device (1) according to any one of Clauses 1-1 to 1-18, wherein the electric field relaxation structure (21) has an impurity concentration higher than the second impurity region (15, 72).

### [Clause 1-20]

The semiconductor device (1) according to Clause 1-19, wherein
an impurity concentration of the second impurity region (15, 72) is not less than 1×10¹⁵ cm⁻³ and not more than 1×10¹⁸ cm⁻³, and
an impurity concentration of the electric field relaxation structures (21) is not less than 1×10¹⁶ cm⁻³ and not more than 1×10¹⁹ cm⁻³.

1. A semiconductor device comprising:
a chip that has a first principal surface and a second principal surface on an opposite side thereto;
a first impurity region of a first conductivity type that is formed in a surface layer portion of the first principal surface;
a second impurity region of a second conductivity type that is formed in a surface layer portion of the first impurity region;
a third impurity region of the first conductivity type that is formed in a surface layer portion of the second impurity region;
a plurality of trenches that reach the first impurity region through the third impurity region and the second impurity region from the first principal surface; and
an electric field relaxation structure of the second conductivity type that is formed integrally with the second impurity region and straddles bottom walls of the plurality of trenches.

2. The semiconductor device according to claim 1, wherein the second impurity region includes a channel portion that is physically and electrically separated from the electric field relaxation structure, and in which a channel is formed along the trench adjacent to the channel portion, and a non-channel portion which is physically and electrically integral with the electric field relaxation structure and has a bottom wall covered with the electric field relaxation structure.

3. The semiconductor device according to claim 2, wherein the channel portion has a width wider than the non-channel portion.

4. The semiconductor device according to claim 2, wherein the electric field relaxation structure has an end portion at a central position of the bottom wall of the trench further to the non-channel portion side than a wall surface of the trench on the channel portion side in a width direction of the trenches.

5. The semiconductor device according to claim 2, wherein the bottom wall of the trench includes a first portion that is formed on the non-channel portion side in the width direction of the trench and covered with the electric field relaxation structure, and a second portion that is formed on the channel portion side with respect to the first portion and covered with the first impurity region.

6. The semiconductor device according to claim 2, wherein
the third impurity region is selectively formed in the channel portion, of the channel portion and the non-channel portion, and
the semiconductor device further comprises a fourth impurity region of the second conductivity type that is formed in the surface layer portion of the second impurity region and has an impurity concentration higher than the second impurity region, and
the fourth impurity region includes a first contact region that is formed in the non-channel portion.

7. The semiconductor device according to claim 6, wherein the fourth impurity region includes a second contact region that, in the channel portion, penetrates the third impurity region and is connected to the second impurity region.

8. The semiconductor device according to claim 7, wherein
the channel portion and the non-channel portion are respectively demarcated by regions sandwiched by the plurality of trenches,
the first contact region is formed over an entirety of the first principal surface between the trench on one side and the trench on the other side of the non-channel portion, and
the second contact region is formed to be sandwiched between a plurality of the third impurity regions arranged contiguous to both of the trench on one side and the trench on the other side of the channel portion.

9. The semiconductor device according to claim 1, wherein
the plurality of electric field relaxation structures are arranged at intervals, and
a pitch of the electric field relaxation structures that are mutually adjacent is not less than twice a pitch of the trenches that are mutually adjacent.

10. The semiconductor device according to claim 9, wherein the pitch of the trenches is not more than 4 μm.

11. The semiconductor device according to claim 9, wherein the pitch of the trenches is not less than 0.5 μm and not more than 3 μm.

12. The semiconductor device according to claim 1, wherein a depth of the electric field relaxation structure is not less than twice a depth of the trench.

13. The semiconductor device according to claim 1, wherein
a depth of the trench is not less than 0.5 μm and not more than 1.5 μm, and
a depth of the electric field relaxation structure is not less than 2 μm and not more than 3 μm.

14. The semiconductor device according to claim 9, wherein the plurality of electric field relaxation structures include at least one of the electric field relaxation structures that straddles the bottom walls of the two trenches which are mutually adjacent.

15. The semiconductor device according to claim 9, wherein the plurality of electric field relaxation structures include at least one of the electric field relaxation structures that straddles the bottom walls of the trenches at both ends among the three consecutive trenches.

16. The semiconductor device according to claim 1, comprising:
a drain region of the first conductivity type that is formed on the second principal surface side with respect to the first impurity region;
a body region that is formed by the second impurity region;
a source region that is formed by the third impurity region; and
a trench gate structure that is formed by the trench, an insulating film covering the wall surface of the trench, and an embedded electrode embedded in the trench.

17. The semiconductor device according to claim 1, comprising:
a collector region of the second conductivity type that is formed on the second principal surface side with respect to the first impurity region;
a base region that is formed by the second impurity region; and
emitter regions that is formed by the third impurity region; and
a trench gate structure that is formed by the trench, an insulating film covering the wall surface of the trench, and an embedded electrode embedded in the trench.

18. The semiconductor device according to claim 1, wherein the chip includes an SiC chip.

19. The semiconductor device according to claim 1, wherein the electric field relaxation structure has an impurity concentration higher than the second impurity region.

20. The semiconductor device according to claim 19, wherein
an impurity concentration of the second impurity region is not less than 1×10¹⁵ cm⁻³ and not more than 1×10¹⁸ cm⁻³, and
an impurity concentration of the electric field relaxation structures is not less than 1×10¹⁶ cm⁻³ and not more than 1×10¹⁹ cm⁻³.
